(19) United States
(12) Patent Application Publication
(10) Pub. No.: US 2026/0271467 A1
(43) Pub. Date: Sep. 10, 2026

(54) LIGHT-EMITTING MODULE

(71) Applicant: NICHIA CORPORATION, Anan-shi (JP)

(72) Inventor: Toshinobu KATSUMATA, Fujiyoshida-shi (JP)

(73) Assignee: NICHIA CORPORATION, Anan-shi (JP)

(21) Appl. No.: 19/555,291

(22) Filed: Mar. 3, 2026

(30) Foreign Application Priority Data
Mar. 6, 2025 (JP) 2025-035722

(51) Int. Cl. H10H 29/855; H10H 20/84; H10H 29/24

(52) U.S. Cl. CPC H10H 29/855; H10H 20/84; H10H 29/24

(57) ABSTRACT

A light-emitting module includes: a lens including: a light incident surface that is recessed upward, and a light exit surface positioned on a side opposite to the light incident surface, the light exit surface including: a flat surface orthogonal to a center line of the lens, and a convex exit surface positioned outside the flat surface in a top view; and at least one first light-emitting unit disposed below the lens and having a predetermined light distribution angle, each of the at least one first light-emitting unit including a first light-emitting surface, a center of the first light-emitting surface being positioned outside the flat surface in the top view. Light beams emitted from a light-emitting point on the first light-emitting surface include: a first light beam that exits upward through the lens above the first light-emitting surface, and a second light beam totally reflected by the flat surface.

### CROSS REFERENCE TO RELATED APPLICATION

This application claims priority to Japanese Patent Applications No. 2025-035722, filed on Mar. 6, 2025, the entire contents of which are hereby incorporated by reference.

### BACKGROUND

### Technical Field

The present disclosure relates to a light-emitting module.

### Background Art

Light-emitting modules including semiconductor elements such as light-emitting diodes (LEDs) have been widely used. As such a light-emitting module, for example, Japanese Patent Publication No. 2013-134898 discloses an illumination device including a light-emitting device including a plurality of light-emitting regions and configured to control each of the light-emitting regions in a light-emitting state different from one another, and an optical member including a plurality of light exit portions disposed to face each of the light-emitting regions of the light-emitting device and to allow output light from each of the light-emitting regions to exit in directions different from one another. In this illumination device, in each of the plurality of light-emitting regions, a plurality of light-emitting elements having different color temperatures for each of the light-emitting regions are two-dimensionally arrayed.

### SUMMARY

An object of an embodiment according to the present disclosure is to reduce unevenness in illuminance distribution in irradiation light.

A light-emitting module according to one embodiment of the present disclosure includes a lens comprising: a light incident surface that is recessed upward, and a light exit surface positioned on a side opposite to the light incident surface, the light exit surface comprising a flat surface orthogonal to a center line of the lens, and a convex exit surface convex upward and positioned outside the flat surface in a top view; and at least one first light-emitting unit disposed below the lens and having a predetermined light distribution angle, each of the at least one first light-emitting unit comprising a first light-emitting surface, a center of the first light-emitting surface being positioned outside the flat surface in the top view. The light-emitting module is configured such that light beams emitted from a light-emitting point on the first light-emitting surface include: a first light beam that exits upward through the lens above the first light-emitting surface, and a second light beam totally reflected by the flat surface.

According to an embodiment of the present disclosure, unevenness in illuminance distribution in irradiation light can be reduced.

### BRIEF DESCRIPTION OF THE DRAWINGS

FIG. 1 is a schematic top view illustrating an overall configuration of a light-emitting module according to a first embodiment.

FIG. 2 is a schematic cross-sectional view taken along the line II-II in FIG. 1.

FIG. 3 is an enlarged schematic view of a first light-emitting unit in FIG. 2.

FIG. 4 is an enlarged schematic view of a light-emitting device in FIG. 2.

FIG. 5A is an image showing a simulation result of illuminance distribution on an irradiation plane when only a first light-emitting unit is allowed to emit light in the light-emitting module according to the first embodiment.

FIG. 5B is a schematic cross-sectional view illustrating a configuration of a light-emitting module according to a first comparative example.

FIG. 5C is an image showing a simulation result of illuminance distribution of irradiation light from the light-emitting module according to the first comparative example.

FIG. 6 is a schematic view illustrating a preferable positional relationship between a lens and the first light-emitting unit included in the light-emitting module according to the first embodiment.

FIG. 7 is a graph showing a simulation result of the illuminance distribution in a cross section including an irradiation center of the irradiation plane of the irradiation light from the light-emitting module according to the first embodiment.

FIG. 8 is a schematic cross-sectional view illustrating behavior of light beams emitted from the light-emitting device of the light-emitting module according to the first embodiment.

FIG. 9 is a schematic view illustrating a relationship between an inclination angle of a convex exit surface in the lens included in the light-emitting module according to the first embodiment and behavior of the light beams exiting from the lens.

FIG. 10 is a schematic top view illustrating an overall configuration of a light-emitting module according to a first modified example.

FIG. 11 is a schematic top view illustrating an overall configuration of a light-emitting module according to a second modified example.

FIG. 12A is an image showing a simulation result of the illuminance distribution on the irradiation plane when only the first light-emitting unit is allowed to emit light in the light-emitting module according to the second modified example.

FIG. 12B is an image showing a simulation result of illuminance distribution of irradiation light from a light-emitting module according to a second comparative example.

FIG. 13 is a schematic view illustrating a preferable positional relationship between the lens and the first light-emitting unit included in the light-emitting module according to the second modified example.

FIG. 14 is a graph showing a simulation result of the illuminance distribution in a cross section including the irradiation center of the irradiation plane of the irradiation light from the light-emitting module according to the second modified example.

FIG. 15 is a schematic top view illustrating an overall configuration of a light-emitting module according to a third modified example.

FIG. 16 is a graph showing a relative luminous efficiency curve in photopic vision and a relative luminous efficiency curve in scotopic vision.

FIG. 17 is a schematic top view illustrating an overall configuration of a light-emitting module according to a fourth modified example.

### DETAILED DESCRIPTION

Light-emitting modules according to embodiments of the present disclosure will be described in detail with reference to the accompanying drawings. However, the embodiments described below exemplify the light-emitting modules for embodying a technical concept of the present embodiment and are not limited to those described below. The dimensions, materials, shapes, relative arrangements, and the like of components described in the embodiments are not intended to limit the scope of the present disclosure, but are merely illustrative examples, unless otherwise specifically stated. The sizes, positional relationship, or the like of members illustrated in the drawings may be exaggerated for clarity of description. In the following description, members having the same terms and reference characters represent the same members or members of the same quality, and a detailed description of these members is omitted as appropriate. As a cross-sectional view, an end view illustrating only a cut surface may be used.

In the following drawings, directions may be indicated by an X-axis, a Y-axis, and a Z-axis corresponding to directions orthogonal to each other. An X direction along the X-axis and a Y direction along the Y-axis indicate directions along a first light-emitting surface of a first light-emitting unit included in the light-emitting module according to the embodiment. A Z direction along the Z-axis indicates a direction orthogonal to the first light-emitting surface. In other words, the first light-emitting surface of the first light-emitting unit is parallel to an XY plane, and the Z-axis is orthogonal to the XY plane.

A direction in which the arrow in the X direction points is defined as the +X side, and a direction opposite to the +X side is defined as the −X side, and a direction in which the arrow in the Y direction points is defined as the +Y side, and a direction opposite to the +Y side is defined as the −Y side. A direction in which the arrow in the Z direction points is defined as the +Z side, and a direction opposite to the +Z side is defined as the −Z side. In the embodiments of the present disclosure, the first light-emitting unit included in the light-emitting module emits light toward the +Z side as an example. However, these definitions do not limit the orientations of the light-emitting modules according to the embodiments of the present disclosure when the light-emitting modules are used, and the light-emitting module according to the embodiment of the present disclosure can be orientated in any direction.

In the present specification, a surface of an object when viewed from the +Z side is referred to as an “upper surface,” and a surface of the object when viewed from the −Z side is referred to as a “lower surface.” In addition, the +Z side when viewed from the object may be referred to as an “upper side,” and the −Z side when viewed from the object may be referred to as a “lower side.” The term “in a top view” used in the embodiments refers to viewing an object from the +Z side. In the present specification, in addition to being used for a portion that is directly visually recognized from above, the term “in a top view” may also be used to describe a portion that is not directly visually recognized from above as if seen through. In the present specification, “along the X-axis, Y-axis, or Z-axis” includes an object having an inclination within a range of ±10° relative to the axis. In the present specification, “orthogonal” may include an error within ±10° with respect to 90°. Furthermore, “disposing” includes not only a case of disposing two objects in direct contact with each other but also includes a case of indirectly disposing, for example, disposing one object in the other object with another member provided therebetween.

In the present specification or the claims, when a plurality of constituent components are provided and these constituent components are to be denoted individually, the constituent components may be distinguished by adding terms such as “first,” “second,” and the like in front of the terms of the constituent components. Objects to be distinguished may differ between the present specification and the claims.

### First Embodiment

### Configuration of Light-Emitting Module According to First Embodiment

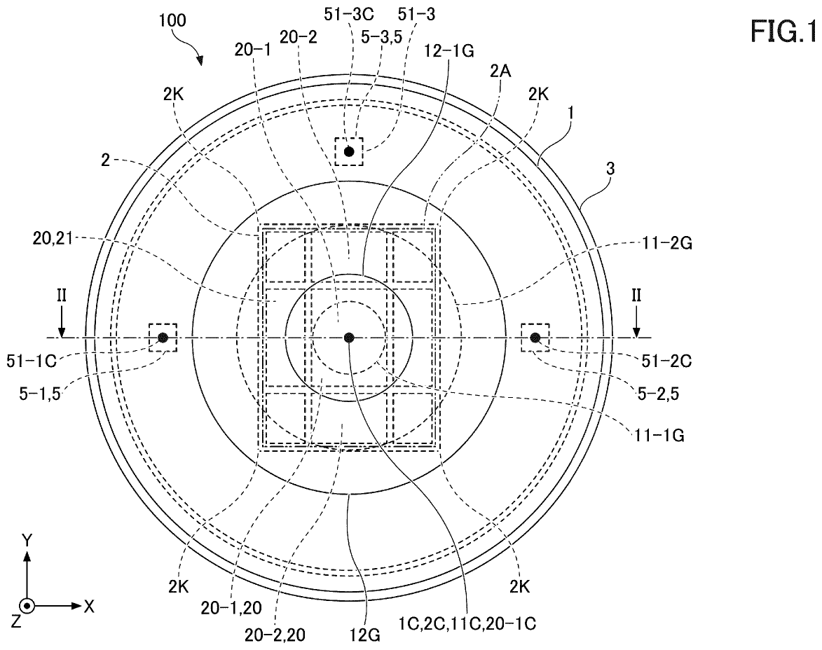

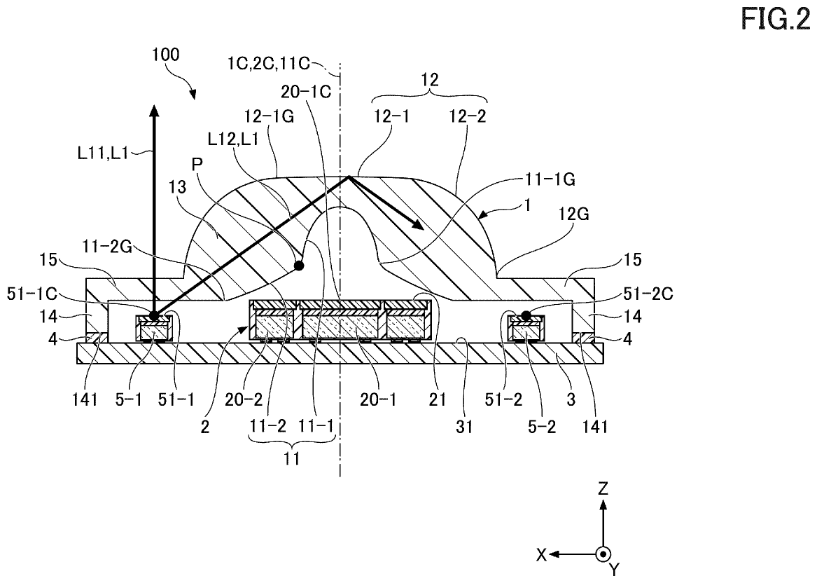

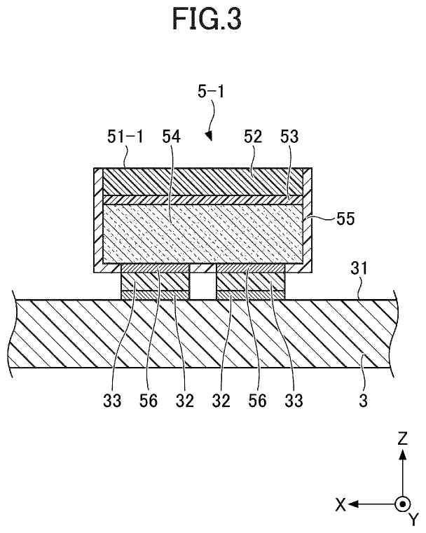

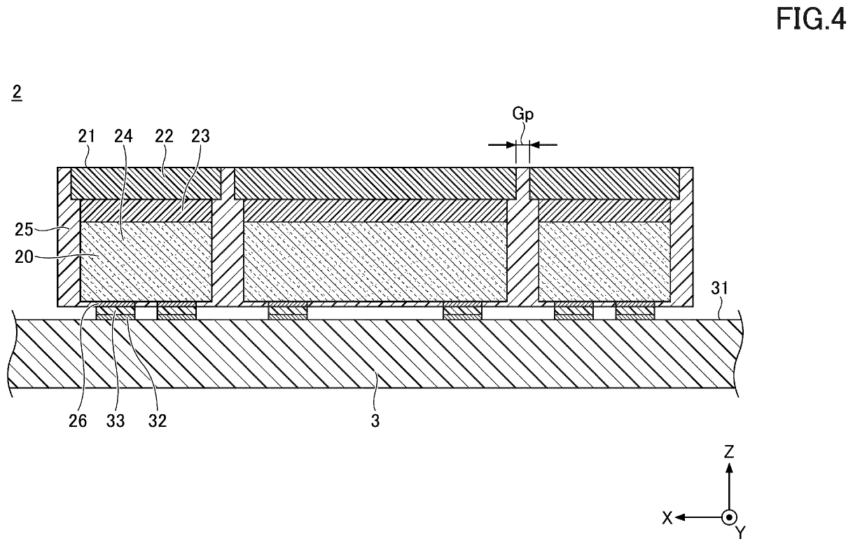

A configuration of a light-emitting module according to a first embodiment of the present disclosure will be described with reference to FIGS. 1 to 4. FIG. 1 is a schematic top view illustrating an overall configuration of a light-emitting module 100 according to the first embodiment of the present disclosure. FIG. 2 is a schematic cross-sectional view taken along the line II-II in FIG. 1. FIG. 3 is an enlarged schematic view of the first light-emitting unit 5-1 in FIG. 2. FIG. 4 is an enlarged schematic view of the light-emitting device 2 in FIG. 2.

The light-emitting module 100 is, as an example, a light source used for a lighting fixture, a flash light source used for an image-capturing device installed in a smartphone, or a light source used for a flashlight (electric torch) function and the like of the smartphone. For example, a light source used in a lighting fixture or the like is required to irradiate an irradiation plane with light in which unevenness in illuminance distribution is reduced. In addition, there is a case in which a plurality of light beams having chromaticities close to each other are required to be superimposed on the irradiation plane to obtain light having high illuminance. In addition, the light source or the like used in the lighting fixture may be required to have a color adjustment function. In the present specification, color adjustment refers to obtaining light having a desired color by superimposing a plurality of light beams having different chromaticities on the irradiation plane.

### Overall Configuration

As illustrated in FIGS. 1 and 2, the light-emitting module 100 includes a lens 1 and at least one first light-emitting unit 5, each of which is disposed below the lens 1 and has a predetermined light distribution angle.

In the examples illustrated in FIGS. 1 and 2, the light-emitting module 100 further includes the light-emitting device 2 having a plurality of second light-emitting units 20. In addition, the light-emitting module 100 further includes a substrate 3 on which the lens 1 and the light-emitting device 2 are disposed, and an adhesive member 4 bonding the lens 1 and the substrate 3.

The light-emitting module 100 can use the light-emitting device 2 as a main light source and at least one first light-emitting unit 5 as an auxiliary light source of the light-emitting device 2. For example, using the at least one first light-emitting unit 5 as the auxiliary light source of the light-emitting device 2 allows the amount of light emitted from the light-emitting module 100 to be increased, or allows the color of the light emitted from the light-emitting module 100 to be adjusted. Note that, in the embodiment of the present disclosure, the light-emitting device 2 is not necessarily an essential component as long as the unevenness in the illuminance distribution is reduced in irradiation light of the at least one first light-emitting unit 5.

In the examples illustrated in FIGS. 1 and 2, the at least one first light-emitting unit 5 includes a first light-emitting unit 5-1, a first light-emitting unit 5-2, and a first light-emitting unit 5-3. The plurality of second light-emitting units 20 include a central light-emitting unit 20-1 and eight outer light-emitting units 20-2 disposed outside the central light-emitting unit 20-1 in a top view. However, the quantity of the at least one first light-emitting unit 5 and the quantity of the plurality of second light-emitting units 20 can be changed as appropriate in accordance with the specifications and the like of the light-emitting module 100. In FIG. 1, to indicate that the at least one first light-emitting unit 5 includes the first light-emitting unit 5-1, the first light-emitting unit 5-2, and the first light-emitting unit 5-3, the reference character of each of the first light-emitting unit 5-1, the first light-emitting unit 5-2, and the first light-emitting unit 5-3 and the reference character of the first light-emitting unit 5 are illustrated together. In addition, to indicate that the plurality of second light-emitting units 20 include the central light-emitting unit 20-1 and the outer light-emitting units 20-2, the reference character of each of the central light-emitting unit 20-1 and the outer light-emitting units 20-2 and the reference character of the second light-emitting unit 20 are illustrated together. Also in the following drawings, reference characters may be additionally written for the same purpose.

The lens 1 and the substrate 3 each have a circular outer shape in a top view. In a top view, an outer shape of the substrate 3 is an outer shape of the light-emitting module 100. However, the lens 1 and the substrate 3 are not limited to a circular shape, and may be another outer shape such as an elliptical shape, a rectangular shape, or a polygonal shape in a top view.

The lens 1 includes a light incident surface 11 that is recessed upward and a light exit surface 12 positioned on a side opposite to the light incident surface 11. The light exit surface 12 includes a flat surface 12-1 that is orthogonal to a center line 1C of the lens 1 and a convex exit surface 12-2 that is positioned outside the flat surface 12-1 in a top view.

In a top view, the first light-emitting unit 5-1, the first light-emitting unit 5-2, and the first light-emitting unit 5-3 are disposed such that a center 51-1C of a first light-emitting surface 51-1 included in the first light-emitting unit 5-1, a center 51-2C of a first light-emitting surface 51-2 included in the first light-emitting unit 5-2, and a center 51-3C of a first light-emitting surface 51-3 included in the first light-emitting unit 5-3 are positioned outward of the flat surface 12-1. Light beams L1 emitted from one light-emitting point in the first light-emitting surface 51-1 include a first light beam L11 that exits upward through the lens 1 above the first light-emitting surface 51-1 and a second light beam L12 that is totally reflected by the flat surface 12-1. The one light-emitting point on the light-emitting surface may be selected from any point positioned on the light-emitting surface. The one light-emitting point on the light-emitting surface is, for example, the geometric center of the light-emitting surface.

In the example illustrated in FIG. 2, in a cross section including the center line 1C of the lens 1 and the first light-emitting unit 5-1 and the first light-emitting unit 5-2, the lens 1 includes a lens outer peripheral portion 15 positioned outside the convex exit surface 12-2. In this case, the lens 1 includes a lens portion 13 positioned above the light-emitting device 2, the lens outer peripheral portion 15 that supports an outer end portion of the lens portion 13, and a support portion 14 that supports the outer end portion of the lens outer peripheral portion 15. In a top view, the lens outer peripheral portion 15 is positioned outside the lens portion 13. The light incident surface 11 includes a lower surface of the lens portion 13. In a case in which the first light-emitting unit 5 is positioned below the lens outer peripheral portion 15, the light incident surface 11 may further include a lower surface (incident surface) of the lens outer peripheral portion 15. The light exit surface 12 includes an upper surface and a lateral surface of the lens portion 13. The lateral surface of the lens portion 13 includes a curved surface. In a case in which the first light-emitting unit 5 is positioned below the lens outer peripheral portion 15, the light exit surface 12 may further include an upper surface (light exit surface) of the lens outer peripheral portion 15. In a top view, a center 20-1C of a second light-emitting surface 21 included in the central light-emitting unit 20-1 is positioned below the flat surface 12-1. The lens 1 is bonded to an upper surface 31 of the substrate 3 by the adhesive member 4 disposed between a lower surface 141 of the support portion 14 and the upper surface 31 of the substrate 3.

In the first embodiment of the present disclosure, in a top view, with the center 51-1C of the first light-emitting surface 51-1 positioned outside the flat surface 12-1 of the lens 1, a light beam L1 emitted from a light-emitting point on the first light-emitting surface 51-1 and transmitted through the lens 1 is likely to be totally reflected by the flat surface 12-1 of the light exit surface 12. In other words, the light beams L1 are likely to include the second light beam L12 that is totally reflected by the flat surface 12-1. With the light beams L1 including the second light beam L12, when the first light-emitting unit 5 is caused to emit light, among the light beams L1 emitted from the first light-emitting unit 5, light traveling in an oblique direction with respect to the center line 1C of the lens 1 after passing through the lens 1 is reduced. In the first embodiment of the present disclosure, by reducing light that travels in the oblique direction with respect to the center line 1C after passing through the lens 1, the unevenness in the illuminance distribution of the light emitted from the at least one first light-emitting unit 5 can be reduced. In addition, the first light beam L11 after passing through the lens 1 can irradiate the vicinity of the center of the irradiation plane on the irradiation plane sufficiently distant from the first light-emitting surface 51-1 (for example, on the irradiation plane positioned 150 mm away from the first light-emitting surface 51-1).

The first light-emitting unit 5-1, the first light-emitting unit 5-2, and the first light-emitting unit 5-3 may be disposed at positions rotationally symmetric with respect to the center line 1C of the lens 1 in a top view. In addition, the first light-emitting unit 5-1 and the first light-emitting unit 5-2 may be disposed at positions symmetric with respect to the center line 1C of the lens 1 in a top view. As a result, the unevenness in the illuminance distribution in the light emitted from a plurality of the first light-emitting units 5 tends to be reduced on the irradiation plane.

The lens outer peripheral portion 15 has an incident surface and an exit surface that are parallel to the first light-emitting surface 51-1, and the center 51-1C of the first light-emitting surface 51-1 may be positioned below the lens outer peripheral portion 15. In other words, in a case in which a light-emitting center of the first light-emitting unit 5 is positioned below the lens outer peripheral portion 15, the lens outer peripheral portion 15 can have the incident surface and the exit surface that are parallel to the first light-emitting surface 51-1. With this structure, the light emitted upward from the first light-emitting unit 5 (for example, the first light beam L11) is less likely to be reflected or refracted into an unintended direction by the incident surface and the exit surface of the lens outer peripheral portion 15, so that the light irradiates a region in the vicinity of the center of the irradiation plane that is sufficiently distant from the first light-emitting surface. As a result, the unevenness in the illuminance distribution on the irradiation plane of the first light-emitting unit 5 can be reduced.

Each of the first light-emitting unit 5-1, the first light-emitting unit 5-2, and the first light-emitting unit 5-3 may be configured to emit white light, blue light, green light, or red light. As an example, the first light-emitting unit 5-1 emits red light, the first light-emitting unit 5-2 emits green light, and the first light-emitting unit 5-3 emits blue light. In the light-emitting module 100, color adjustment can be performed by mixing the light emitted from each of the first light-emitting unit 5-1, the first light-emitting unit 5-2, and the first light-emitting unit 5-3 on the irradiation plane. Further, in the light-emitting module 100, in addition to the light emitted from each of the first light-emitting unit 5-1, the first light-emitting unit 5-2, and the first light-emitting unit 5-3, the light emitted from the light-emitting device 2 may be mixed on the irradiation plane to perform color adjustment. Note that the first light-emitting unit 5 is not limited to the light-emitting unit that emits light of the above colors. The first light-emitting unit 5 may be, for example, a light-emitting unit that emits light having a light emission peak wavelength within a range from 400 nm to 680 nm, may be a light-emitting unit that emits light having a light emission peak wavelength less than 400 nm, for example, in an ultraviolet wavelength region, and may be a light-emitting unit that emits light having a light emission peak wavelength exceeding 680 nm, for example, in an infrared wavelength region.

The first light-emitting unit 5 can be disposed apart from the light-emitting device 2 with a space present therebetween. With this structure, when the first light-emitting unit 5 and the light-emitting device 2 are mounted, the first light-emitting unit 5 and the light-emitting device 2 are less likely to come into contact with each other, or electrical short-circuit between the first light-emitting unit 5 and the light-emitting device 2 is less likely to occur. Further, by disposing the first light-emitting unit 5 and the light-emitting device 2 apart from each other, in a case in which the first light-emitting unit 5 and the light-emitting device 2 are allowed to emit light individually or simultaneously, a degree of freedom in heat dissipation design for each of the first light-emitting unit 5 and the light-emitting device 2 increases. Further, individual control of each of the light emitted from the first light-emitting unit 5 and the light emitted from the light-emitting device 2 by the lens can be facilitated. In a case in which an outer edge shape of the convex exit surface 12-2 in a top view (in other words, an outer shape of an intersection point 12G between the convex exit surface 12-2 and the lens outer peripheral portion 15) is a polygon, the first light-emitting unit 5 is preferably disposed in the vicinity of the center of the side of the polygon. If the first light-emitting unit 5 is disposed in the vicinity of the corner portion of the polygon, the light emitted from the first light-emitting unit 5 is likely to be reflected or refracted by a plurality of surfaces forming the corner portion, so that a good illuminance distribution is sometimes not obtained on the irradiation plane. By disposing the first light-emitting unit 5 in the vicinity of the center of the side of the polygon, optical control by the lens 1 of the light emitted from the first light-emitting unit 5 is facilitated, so that the unevenness in the illuminance distribution on the irradiation plane is likely to be reduced. The first light-emitting unit 5 may be disposed in contact with the light-emitting device 2 without a space therebetween, or the first light-emitting unit 5 may be disposed in the light-emitting device 2 as in a modified example described below.

In an example illustrated in FIG. 2, in one cross section including the center line 1C of the lens 1, the light incident surface 11 includes an inflection point P at which the light incident surface 11 changes from a concave surface to a convex surface. Further, the light incident surface 11 includes a first light incident surface 11-1 positioned above the inflection point P, including a concave surface continuous with the inflection point P, and positioned at the central portion of the light incident surface 11 in a top view. Furthermore, the light incident surface 11 includes a second light incident surface 11-2 positioned below the inflection point P, including a convex surface continuous with the inflection point P, and positioned outside the first light incident surface 11-1 in a top view. Note that the inflection point P refers to a point at which a convex portion and a concave portion are switched from each other. The inflection point P can also be referred to as a point at which the sign of the second order differential changes.

An outer edge 11-1G represents an outer edge of the first light incident surface 11-1. An outer edge 11-2G represents an outer edge of the second light incident surface 11-2. In a top view, the first light incident surface 11-1 has a circular shape centered on a center line 11C, and the second light incident surface 11-2 has an annular shape centered on the center line 11C. An outer edge 12-1G represents an outer edge of the flat surface 12-1. In a top view, the outer edge 12-1G of the flat surface 12-1 is positioned outside an outer edge of the central light-emitting unit 20-1. In addition, in a top view, the flat surface 12-1 has a circular shape centered on the center line 11C, and the convex exit surface 12-2 has an annular shape centered on the center line 11C. A center line 2C represents a line passing through the center of the light-emitting surface of the light-emitting device 2. The center line 11C represents a line passing through the center of the first light incident surface 11-1. The center line 1C of the lens 1, the center line 2C of the light-emitting device 2, and the center line 11C of the first light incident surface 11-1 overlap with each other in a top view. Further, in a top view, at least one outer light-emitting unit 20-2 is disposed overlapping the second light incident surface 11-2.

Here, in the light-emitting module, a lens suitable for variable light distribution is required. The lens suitable for variable light distribution refers to a lens that can change the light distribution of the light emitted from the light-emitting module. In the lens suitable for variable light distribution, a center illuminance of the light emitted from the light-emitting module can preferably be increased, and the illuminance can preferably be made uniform. The center illuminance in the present specification can be regarded as the maximum illuminance of the light emitted from the light-emitting module on the irradiation plane. Further, the uniformity of illuminance can be expressed as “minimum illuminance on the irradiation plane ÷maximum illuminance (center illuminance) on the irradiation plane.” The uniformity of illuminance is measured under the following conditions, for example. On the irradiation plane spaced 150 mm apart from an upper surface of the light-emitting module in the normal direction of the upper surface, a rectangular region of 70 mm×70 mm including the center of the irradiation plane is defined as a first region, a rectangular region of 135 mm×175 mm including the center of the irradiation plane is defined as a second region, and a rectangular region of 260 mm×350 mm including the center of the irradiation plane is defined as a third region. Then, when the light-emitting module emits light having a first light distribution corresponding to the first region, the minimum illuminance and the maximum illuminance in the first region are measured, and an illuminance uniformity A is evaluated. Further, when the light-emitting module emits light having a second light distribution corresponding to the second region, the minimum illuminance and the maximum illuminance in a region of the second region excluding the first region are measured, and an illuminance uniformity B is evaluated. Furthermore, when the light-emitting module emits light having a third light distribution corresponding to the third region, the minimum illuminance and the maximum illuminance in a region of the third region excluding the first region and the second region are measured, and an illuminance uniformity C is evaluated. The light of the second light distribution is a wide-angle light distribution as compared with the light of the first light distribution, and the light of the third light distribution is a wide-angle light distribution as compared with the light of the second light distribution. The illuminance uniformity A is, for example, 50% or more, preferably 60% or more, and more preferably 80% or more. The illuminance uniformity B is, for example, 40% or more, preferably 50% or more, and more preferably 60% or more. The illuminance uniformity C is, for example, 10% or more, preferably 15% or more, and more preferably 20% or more.

For example, in the light-emitting module in which a biconvex lens is disposed above the light-emitting device, increasing curvatures of both a light incident surface and a light exit surface of the biconvex lens are required to increase the illuminance of the irradiation light. When the curvatures of the light incident surface and the light exit surface become larger, an absolute value of refractive power of the biconvex lens becomes larger, increasing stray light that cannot be controlled by the lens, and there may be a case in which light extraction efficiency of the light-emitting module decreases. As a result, an absolute amount of light emitted from the light-emitting module onto the irradiation plane decreases, and an increase in the center illuminance becomes difficult. Furthermore, as the curvatures of the light incident surface and the light exit surface become larger, an incident angle of the light entering the light exit surface after the light receives an optical action on the light incident surface and passes through the inside of the lens tends to become larger. This may increase the amount of light totally reflected by the light exit surface, and increase a light loss. The influence of light emitted from a light-emitting point far from the center among the light-emitting surfaces of the light-emitting module becomes particularly noticeable. As a result, an amount of light controlled to irradiate particularly a region far from the center on the irradiation plane (for example, four corner portions in a case in which an irradiation region is rectangular) decreases, making it difficult to achieve uniform illuminance on the irradiation plane. The “refractive power” indicates a degree to which the traveling direction of incident light is changed. A “positive refractive power” is the refractive power to bend the light toward a converging direction. A “negative refractive power” is the refractive power to bend the light toward a diverging direction. In the present specification, for example, the “positive refractive power” refers to the refractive power that refracts light in a direction approaching the center line 1C of the lens 1, and the “negative refractive power” refers to the refractive power that refracts light in a direction away from the center line 1C of the lens 1. The refractive power includes not only that caused by refraction but also that caused by an optical action other than refraction, such as diffraction or reflection.

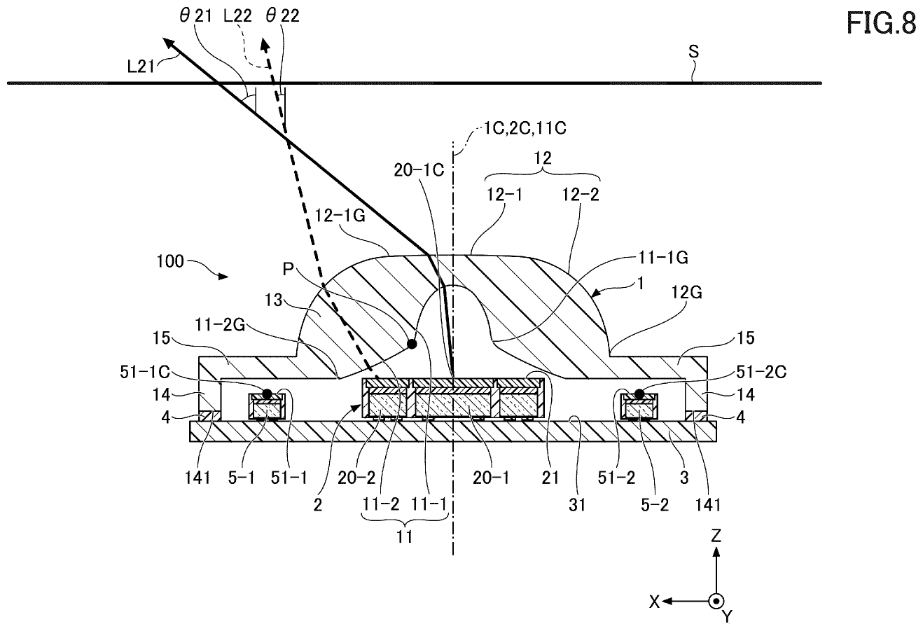

Although behavior of light beams emitted from the light-emitting device 2 will be described in detail below, as represented by a light beam L21 illustrated in FIG. 8, by the negative refractive power obtained by the first light incident surface 11-1 of the light incident surface 11 and the flat surface 12-1 of the light exit surface 12, the light entering the first light incident surface 11-1 from the light-emitting device 2 is refracted in a diverging direction. As a result, the light beam L21 can be used as the light having the wide-angle light distribution. Since the light from the vicinity of the center line 2C in the light-emitting device 2 enters the first light incident surface 11-1, the light entering the first light incident surface 11-1 is easily controlled, the light extraction efficiency is high, and both the Fresnel reflection loss at the light incident surface 11 and the light loss caused by the total reflection at the light exit surface 12 tend to become small. Accordingly, in the wide-angle light distribution, the light-emitting module 100 according to the first embodiment of the present disclosure can emit light in which the center illuminance is high and the illuminance on the irradiation plane can be made uniform.

In addition, in the first embodiment of the present disclosure, as represented by a light beam L22 illustrated in FIG. 8, the light entering the second light incident surface 11-2 from the light-emitting device 2 is refracted in a converging direction by the positive refractive power obtained by the second light incident surface 11-2 of the light incident surface 11 and the convex exit surface 12-2 of the light exit surface 12. As a result, the light beam L22 can be used as the light having the narrow-angle light distribution. In addition, in one cross section, the second light incident surface 11-2 is inclined relative to the center line 1C of the lens 1 at a larger angle than the first light incident surface 11-1. In other words, in one cross section, an angle formed between a tangent line of the second light incident surface 11-2 passing through the inflection point P and the center line 1C of the lens 1 is larger than an angle formed between a tangent line of the first light incident surface 11-1 passing through the inflection point P and the center line 1C of the lens 1. Accordingly, compared with a case in which the first light incident surface 11-1 is extended without having an inflection point P, an incident angle of the light entering the second light incident surface 11-2 is small. That is, the incident angle of the light entering the second light incident surface 11-2 is nearly perpendicular to the second light incident surface 11-2. Therefore, the Fresnel reflection loss tends to be reduced, and the light totally reflected at the second light incident surface 11-2 also tends to be reduced. As a result, the light-emitting module 100 according to the first embodiment of the present disclosure can irradiate light having a high center illuminance and can make the illuminance uniform on the irradiation plane in the narrow-angle light distribution.

As described above, in the first embodiment of the present disclosure, in both the wide-angle light distribution and the narrow-angle light distribution, the center illuminance of the light emitted from the light-emitting module 100 can be increased, and the illuminance of the irradiation light can be made uniform. Thus, in the first embodiment of the present disclosure, the light-emitting module 100 suitable for variable light distribution can be provided. In addition, in the first embodiment of the present disclosure, in the light-emitting module 100 suitable for variable light distribution, the unevenness in the illuminance distribution of the light emitted from the at least one first light-emitting unit 5 can be reduced.

At least one outer light-emitting unit 20-2 can be disposed overlapping the second light incident surface 11-2 in a top view. Accordingly, light emitted from at least one outer light-emitting unit 20-2 can be efficiently entered on the second light incident surface 11-2, and can be used as the light having the narrow-angle light distribution.

In the example illustrated in FIG. 1, the second light-emitting surface 21 indicates a main light extraction surface in the second light-emitting unit 20. Note that, in FIG. 1, reference characters for the second light-emitting unit 20 and the second light-emitting surface 21 are illustrated together to indicate that the second light-emitting unit 20 and the second light-emitting surface 21 overlap each other in a top view. Also in the following drawings, reference characters may be additionally written for the same purpose.

The light-emitting surface of the light-emitting device 2 includes a light-emitting region 2A. The light-emitting region 2A is a region formed by connecting outer edges of the second light-emitting surfaces 21 of the plurality of second light-emitting units 20 positioned on an outer side portion in a top view. In the example illustrated in FIG. 1, the light-emitting region 2A is configured to include nine second light-emitting surfaces 21, and an outer shape of the light-emitting region 2A is rectangular in a top view. The light-emitting region 2A includes four corner portions 2K. In a top view, the center line 2C of the light-emitting device 2 overlaps the center of the light-emitting region 2A. Note that, the outer shape of the light-emitting region 2A and an outer shape of the light-emitting device 2 are not limited to a rectangular shape in a top view, and may be another shape such as a circular shape, an elliptical shape, or a polygonal shape.

Light emission control can be performed on the nine second light-emitting units 20. That is, in the light-emitting device 2, the nine second light-emitting units 20 may be driven individually or in a plurality of groups. The nine second light-emitting units 20 can emit light toward the lens 1 located above the light-emitting device 2. The light-emitting module 100 can control the light distribution of the emitted light of the light-emitting module 100 by controlling a current supplied to each of the second light-emitting units 20 or to each group of the second light-emitting units 20.

The light-emitting module 100 can turn on each of the nine second light-emitting units 20 at a desired brightness individually or in groups. As a result, the contrast of the irradiation light on the irradiation plane irradiated with the light emitted from the light-emitting device 2 is increased. In addition, the light-emitting module 100 can partially irradiate the irradiation plane by turning on each of the nine second light-emitting units 20 individually or in groups. The “partially irradiate” refers to irradiating a part of the region of the irradiation plane with light.

Each constituent component of the light-emitting module 100 will be described in detail below.

### Lens 1

The lens 1 is configured to include at least one of resin materials such as polycarbonate resin, acrylic resin, silicone resin, and epoxy resin, or a glass material having transmissivity with respect to the light emitted from the light-emitting device 2. In the example illustrated in FIG. 2, the lens portion 13, the support portion 14, and the lens outer peripheral portion 15 are connected to each other as an integral member. However, the lens portion 13, the support portion 14, and the lens outer peripheral portion 15 may be separate members. Note that, transmissivity in the lens 1 refers to a property that allows transmission of 60% or more of light emitted from the light-emitting device 2.

In the example illustrated in FIG. 1, the light exit surface 12 has a circular outer shape in a top view. However, an outer shape of the light exit surface 12 is not limited to a circular shape, and may be another outer shape such as a rectangular shape, an elliptical shape, or a polygonal shape in a top view. Further, the light exit surface 12 may have a rotationally symmetrical shape in a top view. In consideration of the fact that a shooting range of a general imaging device is rectangular, the light exit surface 12 preferably has four-fold rotational symmetry or two-fold rotational symmetry in a top view.

The flat surface 12-1 has a circular outer shape in a top view. However, an outer shape of the flat surface 12-1 is not limited to a circular shape, and may be a rectangular shape, an elliptical shape, a polygonal shape or other outer shape in a top view. The convex exit surface 12-2 is positioned outside the flat surface 12-1, and has a circular annular shape centered on the center line 11C in a top view. However, the shape of the convex exit surface 12-2 is not limited to a circular shape, and may be an annular shape such as a rectangular shape, an elliptical shape, or a polygonal shape in a top view.

The support portion 14 is a portion that supports the lens portion 13 from the outer side in a top view. In addition, the support portion 14 is a circular annular shape centered on the center line 11C in a top view. However, the support portion 14 is not limited to a circular shape in a top view, and may have an annular shape such as a rectangular shape, an elliptical shape, or a polygonal shape. In addition, the support portion 14 may be disposed intermittently in an annular arrangement in a top view.

In the example illustrated in FIG. 2, the first light incident surface 11-1 has an aspherical shape that is concave. However, the first light incident surface 11-1 may have a spherical shape that is concave. The second light incident surface 11-2 has a circular annular shape centered on the center line 11C in a top view. However, the shape of the second light incident surface 11-2 in a top view is not limited to a circular shape, and may be an annular shape such as a rectangular shape, an elliptical shape, or a polygonal shape. The second light incident surface 11-2 has an aspherical shape that is convex in a cross section including the center line 1C of the lens 1. However, the second light incident surface 11-2 may have a spherical shape that is convex. The flat surface 12-1 is a flat surface parallel to the upper surface 31 of the substrate 3. The flat surface 12-1 can be configured to include a rough surface. The rough surface on the flat surface 12-1 is, for example, fine protrusion and recession having an arithmetic average roughness Ra within a range from 0.2 μm to 18 μm. The rough surface on the flat surface 12-1 is obtained by sandblasting or the like. With the flat surface 12-1 including the rough surface, the light-emitting device 2 inside is less visible when the light-emitting module 100 is viewed from above, so that the appearance of the light-emitting module 100 is improved. In a case in which the light-emitting module 100 is used as a flash light source in a mobile communication terminal, the light-emitting device 2 inside may be visible through the lens 1 from the outside of the housing. The light-emitting module having a good appearance refers to, for example, a light-emitting module having a simple appearance in which the light-emitting device 2 inside is less visible. Accordingly, a degree of freedom in design of a mobile communication terminal is improved without impairing the appearance of the entire mobile communication terminal.

### First Light-Emitting Unit 5

With reference to FIGS. 1 and 3, a configuration of the first light-emitting unit 5 will be described in detail. Note that, the same configuration can be used for the first light-emitting unit 5-1, the first light-emitting unit 5-2, and the first light-emitting unit 5-3. Therefore, in the following description, a configuration of the first light-emitting unit 5-1 will be representatively described.

The first light-emitting unit 5-1 includes the first light-emitting surface 51-1 on an upper surface, and is disposed on the upper surface 31 of the substrate 3 with a surface opposite to the first light-emitting surface 51-1 serving as a mounting surface.

In the example illustrated in FIG. 3, the first light-emitting unit 5-1 includes a light-emitting element 54, a wavelength conversion member 53 disposed above the light-emitting element 54, and a light diffusion member 52 disposed above the wavelength conversion member 53. Further, the first light-emitting unit 5-1 includes a covering member 55 that covers lateral surfaces of each of the light diffusion member 52, the wavelength conversion member 53, and the light-emitting element 54.

The light-emitting element 54 is disposed on a wiring 32 of the substrate 3 with a conductive member 33 interposed therebetween. A lower surface side of the light-emitting element 54 and a lateral surface of an electrode 56 of the light-emitting element 54 are covered with the covering member 55. The covering member 55 integrally holds the light diffusion member 52, the wavelength conversion member 53, and the light-emitting element 54. An upper surface of the covering member 55 forms a part of an upper surface of the first light-emitting unit 5-1. In addition, the covering member 55 has four lateral surfaces that form a rectangular outer shape of the first light-emitting unit 5-1 in a top view.

The light-emitting element 54 has a semiconductor structure including a III-V group compound semiconductor, a II-VI group compound semiconductor, or the like. As the semiconductor, a nitride-based semiconductor such as In_{X}Al_{Y}Ga_{1-X-Y}N (0≤X, 0≤Y, X+Y≤1) is preferably used, and a semiconductor including one or more selected from the group consisting of InN, AlN, GaN, InGaN, AlGaN, InGaAlN, and the like may be used. In addition, the light-emitting element 54 may use a semiconductor including one or more selected from the group consisting of InAlGaP, GaInP, GaAs, and AlGaAs. The light-emitting element 54 is an LED or a laser diode (LD), for example. The semiconductor structure of the light-emitting element 54 is provided on a growth substrate such as sapphire. Note that, the light-emitting element 54 may be obtained by forming a semiconductor structure on the growth substrate, and then removing the growth substrate. From the viewpoints of light emission efficiency and excitation of a wavelength conversion substance described below, a light emission peak wavelength of the light-emitting element 54 is preferably within a range from 400 nm to 680 nm, more preferably within a range from 420 nm to 490 nm, and further preferably within a range from 450 nm to 475 nm.

The wavelength conversion member 53 is, for example, a member having a rectangular shape in a top view. The wavelength conversion member 53 covers an upper surface of the light-emitting element 54. The wavelength conversion member 53 contains the wavelength conversion substance that converts a wavelength of at least part of the light from the light-emitting element 54. The wavelength conversion member 53 may be formed using a light-transmissive resin material or an inorganic material such as ceramics or glass. As the resin material, a thermosetting resin, such as a silicone resin, a silicone modified resin, an epoxy resin, an epoxy modified resin, or a phenol resin, can be used. Particularly, a silicone resin or a modified resin thereof with high light resistance and heat resistance is used. Note that the term “light-transmissive” here preferably refers to transmission of 60% or more of the light from the light-emitting element 54. In addition, the wavelength conversion member 53 may use a thermoplastic resin, such as a polycarbonate resin, an acrylic resin, a methyl pentene resin, or a polynorbornene resin. For example, the wavelength conversion member 53 may be made of a resin material, ceramics, glass, or the like containing a wavelength conversion substance, or may be a sintered body of the wavelength conversion substance or the like. Further, the wavelength conversion member 53 may contain a light diffusion substance described below in the resin described above. In addition, the wavelength conversion member 53 may also be a multilayer member in which a resin layer containing the wavelength conversion substance or the light diffusion substance is disposed on one surface or both surfaces of a molded body of resin, ceramics, glass, or the like.

As the wavelength conversion substance included in the wavelength conversion member 53, for example, an yttrium aluminum garnet-based phosphor (for example, (Y, Gd)₃(Al, Ga)₅O₁₂:Ce), a lutetium aluminum garnet-based phosphor (for example, Lu₃(Al, Ga)₅O₁₂:Ce), a terbium aluminum garnet-based phosphor (for example, Tb₃(Al, Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba, Sr, Ca, Mg)₂SiO₄:Eu), an oxynitride-based phosphor such as a β-SiAlON-based phosphor (for example, (Si, Al)₃(O, N)₄:Eu) or an α-SiAlON-based phosphor (for example, Ca(Si, Al)₁₂(O, N)₁₆:Eu), a nitride-based phosphor such as an LSN-based phosphor (for example, (La, Y)₃Si₆N₁₁:Ce), a BSESN-based phosphor (for example, (Ba, Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr, Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs, FA, MA)(Pb, Sn)(F, Cl, Br, I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag, Cu)(In, Ga)(S, Se)₂), or the like can be used. The wavelength conversion substance described above is in the form of particles. Further, one of these types of wavelength conversion substances can be used alone, or two or more of these types of wavelength conversion substances can be used in combination.

By including the light-emitting element 54 and the wavelength conversion member 53, the first light-emitting unit 5-1 can emit the mixed light of the color of the light emitted from the light-emitting element 54 and the color of the light emitted from the wavelength conversion member 53. In the first light-emitting unit 5-1, a degree of freedom of the color of the light emitted from the first light-emitting unit 5-1 increases by the combination of the light-emitting element 54 and the wavelength conversion member 53.

As one example, the first light-emitting unit 5-1 uses a blue LED as the light-emitting element 54, and the wavelength conversion member 53 contains a wavelength conversion substance that performs wavelength conversion of the light emitted from the light-emitting element 54 into yellow light. Thus, the first light-emitting unit 5-1 emits white light. According to an intended use or an application of the light-emitting module 100, the wavelength or chromaticity of the light emitted from the first light-emitting unit 5-1 may be appropriately selected.

The light diffusion member 52 is a member that diffuses light from the light-emitting element 54 and the wavelength conversion member 53, and is, for example, a member having a rectangular shape in a top view. The light diffusion member 52 has, as a base material, the same resin material as that of the wavelength conversion member 53, and may contain, as a light diffusion substance, for example, titanium oxide, barium titanate, aluminum oxide, or silicon oxide. In the example illustrated in FIG. 3, an upper surface of the light diffusion member 52 is exposed from the covering member 55 and corresponds to the first light-emitting surface 51-1 of the first light-emitting unit 5-1. The center 51-1C of the first light-emitting surface 51-1 is positioned on the light diffusion member 52.

The covering member 55 directly or indirectly covers the lateral surfaces of the light diffusion member 52, the wavelength conversion member 53, and the light-emitting element 54. The covering member 55 is preferably made of a member having high light reflectivity. By covering the light diffusion member 52, the wavelength conversion member 53, and the light-emitting element 54 with the covering member 55, light leaking from these members is reduced, and light can be efficiently extracted from the first light-emitting surface 51-1. Accordingly, the light extraction efficiency of the first light-emitting unit 5-1 increases. The covering member 55 may be made of a resin material containing a light diffusion substance such as a white pigment, for example. In addition, the covering member 55 may be a light-reflective member made of an inorganic material containing, for example, boron nitride or an alkali metal silicate. In this case, titanium oxide or zirconium oxide can be further contained.

Examples of the light diffusion substance contained in the covering member 55 include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide, and one of these types of substances may be used alone or a combination of two or more of these types of substances may be preferably used. For the resin material, a resin material containing a thermosetting resin, such as an epoxy resin, an epoxy modified resin, a silicone resin, a silicone modified resin, or a phenol resin, as a main component is preferably used as a base material. The covering member 25 may be constituted by a member having transmissivity or absorbency for visible light as necessary. The member having the absorbency contains, for example, carbon black.

The first light-emitting unit 5-1 is electrically connected to the wiring 32 included in the substrate 3. The substrate 3 includes the wirings 32 disposed on a surface. The substrate 3 may include the wirings 32 therein. The first light-emitting unit 5-1 and the substrate 3 are electrically connected by connecting the wiring 32 of the substrate 3 and the electrode 56 of the light-emitting element 54 with the conductive member 33 interposed therebetween. Note that, a configuration, size, and the like of the wiring 32 of the substrate 3 are set according to a configuration and size of the electrode 56 of the light-emitting element 54.

### Illuminance Distribution and Illuminance of Irradiation Light When First Light-Emitting Unit 5 is Allowed to Emit Light

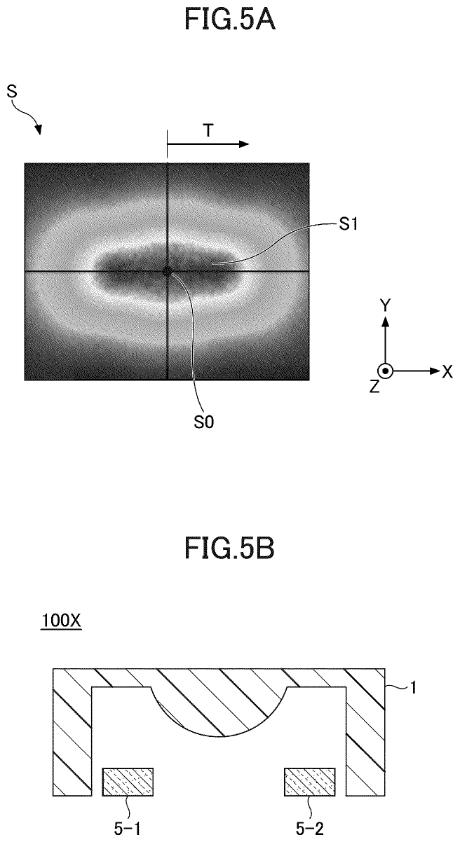

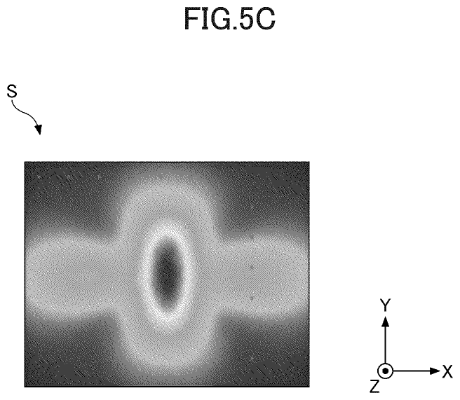

With reference to FIGS. 5A, 5B, 5C, 6, and 7, the following describes illuminance distribution and illuminance of irradiation light from the light-emitting module 100 when only the first light-emitting unit 5 is caused to emit light without causing the light-emitting device 2 to emit light. The illuminance distribution and the illuminance of the irradiation light illustrated in FIG. 5A and the like represent the illuminance distribution and the illuminance of the irradiation light when the first light-emitting unit 5-1 and the first light-emitting unit 5-2 are allowed to emit light.

FIG. 5A is an image showing a simulation result of the illuminance distribution on an irradiation plane S when only the first light-emitting unit 5 is allowed to emit light in the light-emitting module 100. FIG. 5A shows the illuminance distribution on the irradiation plane S viewed from the +Z side. In FIG. 5A, a color in the drawing that is closer to white represents that the illuminance of the irradiation light is higher. Note that, as an exception, a black region S1 including an irradiation center S0 has a higher illumination than that of the white region.

In FIG. 5A, the irradiation center S0 represents the center of the irradiation plane S. The distance T is a distance from the irradiation center S0. In the example illustrated in FIG. 5A, the distance T is a distance from the irradiation center S0 in the X direction. The distance T on the +X side with respect to the irradiation center S0 is represented by a positive value. The distance T on the −X side with respect to the irradiation center S0 is represented by a negative value.

FIG. 5B is a schematic cross-sectional view illustrating a configuration of a light-emitting module 100X according to a first comparative example. FIG. 5C is an image showing a simulation result of an illuminance distribution of irradiation light from the light-emitting module 100X according to the first comparative example. In FIGS. 5B and 5C, for convenience of explanation, components having the same functions as those of components of the light-emitting module 100 are denoted by the same reference characters as those of the components of the light-emitting module 100. This applies also to a second comparative example illustrated below.

As shown in FIG. 5C, a finding has been obtained that the non-uniformity occurs in the illuminance distribution in the irradiation light within the irradiation plane S in the light-emitting module 100X according to the first comparative example.

On the other hand, in a simulation result illustrated in FIG. 5A, a substantially elliptical illuminance distribution centered on the irradiation center S0 was obtained. With this, a finding has been obtained that, in the light-emitting module 100, the unevenness in the illuminance distribution in the irradiation light can be reduced as compared with the light-emitting module 100X according to the first comparative example in which a shape of the illuminance distribution is a distorted shape. In addition, in the simulation result illustrated in FIG. 5A, the substantially elliptical illuminance distribution having a length approximately equal to the length of the irradiation plane S was obtained at least in the X direction. Accordingly, a finding has been obtained that, in the light-emitting module 100, the unevenness in the illuminance distribution in the irradiation light within the irradiation plane S can be reduced as compared with a case illustrated in FIG. 5C in which the illuminance is high only in a part of the irradiation plane S and the illuminance is low in other regions. From these results, a finding has been obtained that, in the light-emitting module 100, the unevenness in the illuminance distribution in the irradiation light can be reduced.

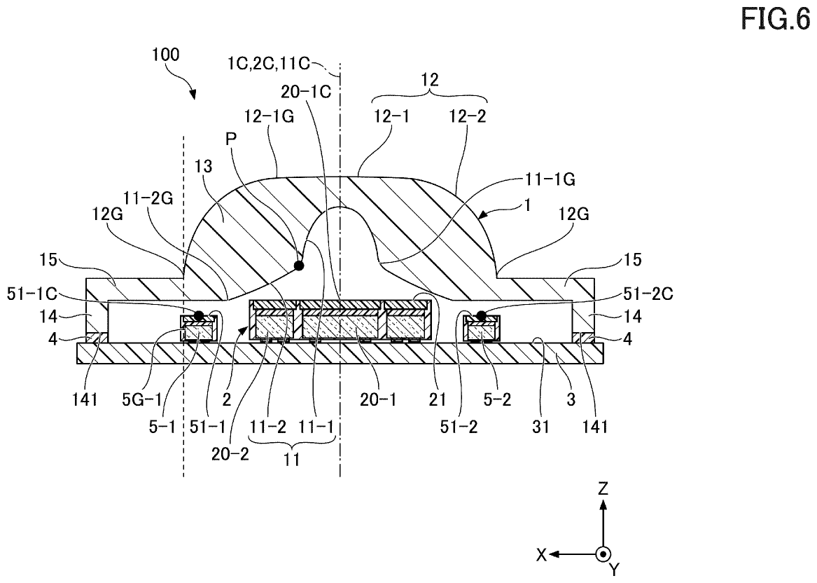

FIG. 6 is a schematic view illustrating a preferable positional relationship between the lens 1 and the first light-emitting unit 5 included in the light-emitting module 100. As a result of study, a finding has been obtained that, in the first embodiment of the present disclosure, in a top view, in a case in which an outer edge 5G-1 on the side opposite to the side where the center line 1C of the lens 1 is positioned in each of the first light-emitting surface 51-1 of the first light-emitting unit 5-1 and the first light-emitting surface 51-2 of the first light-emitting unit 5-2 overlaps the intersection point 12G between the convex exit surface 12-2 and the lens outer peripheral portion 15, or is positioned outside the intersection point 12G, a preferable illuminance distribution can be obtained. In addition, in particular, a finding has been obtained that, in a top view, in a case in which the outer edge 5G-1 on the side opposite to the side where the center line 1C of the lens 1 is positioned in each of the first light-emitting surface 51-1 of the first light-emitting unit 5-1 and the first light-emitting surface 51-2 of the first light-emitting unit 5-2 overlaps the intersection point 12G between the convex exit surface 12-2 and the lens outer peripheral portion 15, an optimal illuminance distribution can be obtained. In other words, at least one of the first light-emitting units 5 includes two of the first light-emitting units 5, and, in a top view, in a case in which the outer edge 5G-1 on the side opposite to the side where the center line 1C of the lens 1 is positioned in each of the first light-emitting surface 51-1 and the first light-emitting surface 51-2 overlaps with the intersection point 12G between the convex exit surface 12-2 and the lens outer peripheral portion 15, an optimal illuminance distribution can be obtained. Note that the optimal illuminance distribution refers to the illuminance distribution in which the unevenness in the illuminance distribution in the irradiation light is most reduced.

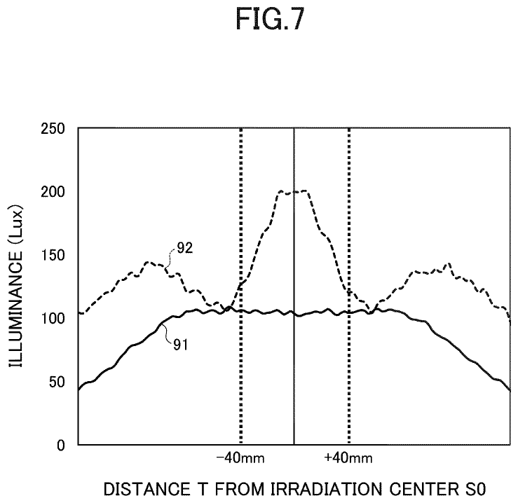

FIG. 7 is a graph showing a simulation result of the illuminance distribution in a cross section including the irradiation center S0 of the irradiation plane S of the irradiation light from the light-emitting module 100. FIG. 7 illustrates the illuminance distribution on the irradiation plane S positioned 150 mm away from the first light-emitting surface 51-1 in a direction orthogonal to the first light-emitting surface 51-1, for example, in the Z direction, in a cross section including the irradiation center S0 of the irradiation plane S. The horizontal axis corresponds to the distance T illustrated in FIG. 5A.

In FIG. 7, a graph 91 illustrated by a solid line represents the simulation result of the light-emitting module 100 according to the first embodiment of the present disclosure. A graph 92 illustrated by a broken line represents the simulation result of the light-emitting module 100X according to the first comparative example.

As shown in FIG. 7, the ratio of the minimum illuminance to the maximum illuminance at a distance T within the range from −40 mm to 40 mm on the irradiation plan is 60.0% in the light-emitting module 100X according to the first comparative example, while the ratio is 95.1% in the light-emitting module 100. From this result, a finding has been obtained that the light-emitting module 100 can reduce the unevenness in the illuminance distribution in the irradiation light. In the light-emitting module 100 according to the present embodiment, the ratio of the minimum illuminance to the maximum illuminance at a distance T within the range from −40 mm to 40 mm on the irradiation plane is, for example, greater than 60% and preferably 70% or more, more preferably 80% or more, and further preferably 90% or more.

### Light-Emitting Device 2

Returning to FIGS. 1 and 4, a configuration of the light-emitting device 2 will be described in detail. The light-emitting device 2 includes the second light-emitting surface 21 of the second light-emitting unit 20 on an upper surface, and is disposed on the upper surface 31 of the substrate 3 with a surface opposite to the second light-emitting surface 21 serving as a mounting surface. Note that nine second light-emitting units 20 included in the light-emitting device 2 each have substantially the same configuration. Therefore, in the following description, a configuration of the second light-emitting unit 20 disposed in the second row and the first column may be representatively described.

In an example illustrated in FIG. 4, the second light-emitting unit 20 includes a light-emitting element 24, a wavelength conversion member 23 disposed above the light-emitting element 24, and a light diffusion member 22 disposed above the wavelength conversion member 23. Further, the second light-emitting unit 20 includes a covering member 25 that covers respective lateral surfaces of the light diffusion member 22, the wavelength conversion member 23, and the light-emitting element 24.

The light-emitting element 24 is disposed on the wiring 32 of the substrate 3 with the conductive member 33 interposed therebetween. A lower surface side of the light-emitting element 24 and lateral surfaces of electrodes 26 of the light-emitting element 24 are covered with the covering member 25.

The covering member 25 integrally holds a plurality of the light diffusion members 22, a plurality of the wavelength conversion members 23, and a plurality of the light-emitting elements 24. From another viewpoint, the plurality of second light-emitting units 20 are integrally held by the covering member 25. By the covering member 25 integrally holding the plurality of second light-emitting units 20, an area of the light-emitting region 2A of the light-emitting device 2 can be reduced as compared with a case in which the covering members of the plurality of second light-emitting units are separated from each other. As a result, the lens 1 disposed above the light-emitting device 2 can be made smaller. In addition, by the covering member 25 integrally holding the plurality of light diffusion members 22, the plurality of wavelength conversion members 23, and the plurality of light-emitting elements 24, mounting of the light-emitting device 2 becomes easier.

In an example illustrated in FIG. 4, the covering member 25 is disposed between the adjacent light diffusion members 22, between the adjacent wavelength conversion members 23, and between the adjacent light-emitting elements 24, respectively. An upper surface of the covering member 25 constitutes a part of an upper surface of the light-emitting device 2. In addition, the covering member 25 includes two long lateral surfaces and two short lateral surfaces, and the four lateral surfaces form a rectangular outer shape of the light-emitting device 2 in a top view. In the light-emitting device 2, a gap Gp between the adjacent second light-emitting surfaces 21 is, for example, within a range from 10 μm to 50 μm.

By the light-emitting device 2 including the plurality of second light-emitting units 20, a degree of freedom of patterns of the light that can be emitted from the light-emitting device 2 increases. In addition, performing light emission control on the plurality of second light-emitting units 20 facilitate uniform light irradiation on the irradiation plane.

The same type as the light-emitting element 54 of the first light-emitting unit 5-1 may be used for the light-emitting element 24. The same type as the wavelength conversion member 53 of the first light-emitting unit 5-1 may be used for the wavelength conversion member 23. The same type as the light diffusion member 52 of the first light-emitting unit 5-1 may be used for the light diffusion member 22. The same type as the covering member 55 of the first light-emitting unit 5-1 may be used for the covering member 25. Therefore, redundant descriptions of these components are omitted here. Note that the first light-emitting unit 5-1 and the second light-emitting unit 20 do not necessarily have the same configuration.

The light-emitting device 2 is electrically connected to the wiring 32 included in the substrate 3. The configuration, size, and the like of the wirings 32 of the substrate 3 are set according to a configuration and size of the electrode 26 of the light-emitting element 24.

### Substrate 3

The substrate 3 is a substrate including wirings on which the first light-emitting unit 5 and the light-emitting device 2 can be mounted. Note that electronic components other than the first light-emitting unit 5 and the light-emitting device 2 may be further disposed on the substrate 3. The electronic component is a Zener diode, a thermistor, a capacitor, a light-receiving sensor, or the like.

For the substrate 3, an insulating material is preferably used as a base material, and a material that is less likely to transmit light emitted from the first light-emitting unit 5 and the light-emitting device 2, light entering from the outside into the inside of the light-emitting module 100, and the like is preferably used. Further, for the substrate 3, a material having a certain degree of strength is preferably used. Specifically, the substrate 3 may be made of ceramics, such as aluminum oxide, aluminum nitride, mullite, or silicon nitride, or a resin, such as a phenol resin, an epoxy resin, a polyimide resin, a bismaleimide triazine resin (BT resin), a polyphthalamide resin, and a polyester resin, as the base material.

The wirings 32 of the substrate 3 can be made of at least one type of copper, iron, nickel, tungsten, chromium, aluminum, silver, gold, titanium, palladium, rhodium, an alloy thereof, or the like. Furthermore, a layer of silver, platinum, aluminum, rhodium, gold, an alloy thereof, or the like may be provided on the surface layer of the wirings 32 of the substrate 3, from the viewpoint of at least one of the wettability or light reflectivity of the conductive member.

The first light-emitting unit 5 and the light-emitting device 2 are mounted on the upper surface 31 of the substrate 3. In an example illustrated in FIG. 1, the light-emitting device 2 has a rectangular outer shape in a top view. The light-emitting device 2 includes nine second light-emitting units 20 disposed in a matrix pattern. In the nine second light-emitting units 20, three second light-emitting units 20 are aligned in a row direction (for example, the X direction), and three second light-emitting units 20 are aligned in a column direction (for example, the Y direction).

The light-emitting module 100 can change the light distribution by switching between the wide-angle light distribution obtained by turning on the second light-emitting units 20 including at least the central light-emitting unit 20-1 and the narrow-angle light distribution obtained by turning on the second light-emitting units 20 including at least one outer light-emitting unit 20-2.

In an example illustrated in FIG. 1, one or more outer light-emitting units 20-2 of a plurality of the outer light-emitting units 20-2 are disposed overlapping the second light incident surface 11-2 in a top view. The term “overlap” includes a case in which one is disposed inside the other and overlaps the other, and also includes a case in which one and the other partially overlap each other. By one or more of the outer light-emitting units 20-2 being disposed to overlap the second light incident surface 11-2 in a top view, the light emitted from the outer light-emitting unit 20-2 tends to bend in a converging direction due to the positive refractive power obtained by the second light incident surface 11-2 and the convex exit surface 12-2. As a result, the light entering the lens 1 through the second light incident surface 11-2 from the light-emitting device 2 becomes easier to control.

In an example illustrated in FIG. 1, in a top view, the flat surface 12-1 overlaps the central light-emitting units 20-1, and the convex exit surface 12-2 overlaps one or more of the outer light-emitting units 20-2 among the plurality of outer light-emitting units 20-2. In addition, the eight outer light-emitting units 20-2 are positioned inside the intersection point 12G (in other words, an outer edge of the convex exit surface 12-2) and overlap the convex exit surface 12-2 in a top view. By the flat surface 12-1 overlapping the central light-emitting units 20-1 in a top view, the light emitted from the central light-emitting unit 20-1 is made easier to diverge and refract outward by the flat surface 12-1 having the negative refractive power. In addition, by the convex exit surface 12-2 overlapping one or more of the outer light-emitting units 20-2 in a top view, the light emitted from the outer light-emitting units 20-2 is made easier to converge and refract inward by the convex exit surface 12-2 having the positive refractive power. Further, performing light emission control on the central light-emitting unit 20-1 and the outer light-emitting units 20-2 enables the switching of the light distribution. The light emission control of the central light-emitting unit 20-1 and the outer light-emitting units 20-2 includes allowing at least one of the central light-emitting unit 20-1 and the outer light-emitting units 20-2 to emit light or to be turned off, or controlling the light emission intensity of at least one of the central light-emitting unit 20-1 and the outer light-emitting units 20-2.

In the light-emitting module 100, the irradiation light in a wide-angle mode and the irradiation light in a narrow-angle mode can be switched. The wide-angle mode is an irradiation mode in which the central light-emitting unit 20-1 is mainly allowed to emit light. The irradiation light in the wide-angle mode has the wide-angle light distribution. The narrow-angle mode is an irradiation mode in which the outer light-emitting units 20-2 are mainly allowed to emit light. The irradiation light in the narrow-angle mode has the narrow-angle light distribution. That is, a light distribution angle of the irradiation light in the narrow-angle mode is narrower than a light distribution angle of the irradiation light in the wide-angle mode. The light-emitting module 100 may also switch between the wide-angle light distribution and the narrow-angle light distribution by adjusting light intensity of each of the central light-emitting unit 20-1 and the outer light-emitting units 20-2 to irradiate light.

Since the light-emitting module 100 can switch irradiation light between the wide-angle mode and the narrow-angle mode, for example, by using the light emitted from the light-emitting module 100, the irradiation with the different light distributions becomes possible with a lighting fixture. In addition, the imaging device can provide the irradiation light corresponding to a shooting mode such as a close-up mode or a telephoto mode. Further, in a case in which the light-emitting module 100 is used as a light source for a flashlight of a smartphone or the like, performance of the flashlight can be enhanced by setting the light emitted from the light-emitting module 100 to the narrow-angle mode so that the irradiation light reaches a distant area. The performance of the flashlight refers to, for example, providing light having sufficient illuminance for a target object, having light-converging capability that enables irradiation of only a necessary region, or having good energy efficiency.

### Behavior of Light Beams Emitted From Light-Emitting Device 2

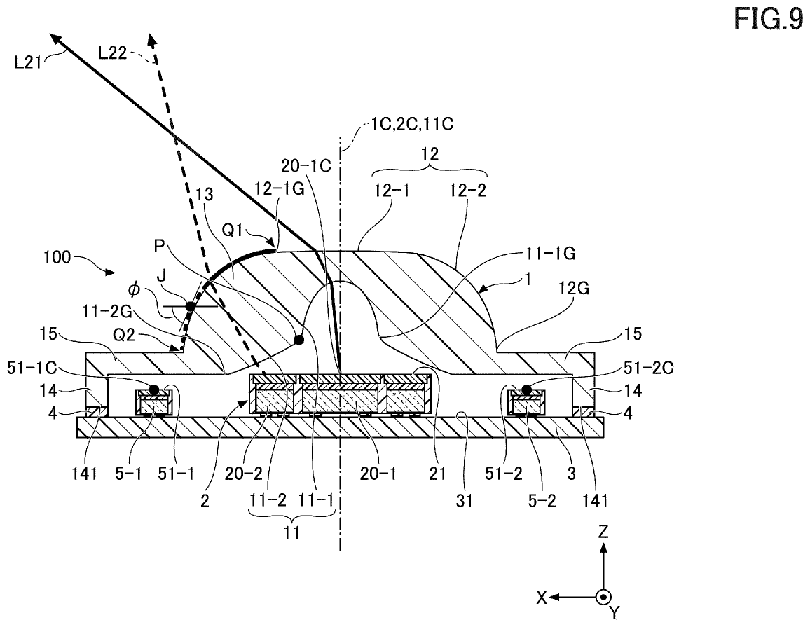

With reference to FIGS. 8 and 9, behavior of the light beams emitted from the light-emitting device 2 will be described in detail. FIG. 8 is a schematic cross-sectional view of the light-emitting module 100 illustrating behavior of the light beams emitted from the light-emitting device 2. FIG. 9 is a schematic view illustrating a relationship between an inclination angle φ of the convex exit surface 12-2 of the lens 1 and behavior of light beams exiting from the lens 1.

FIG. 8 illustrates a cross section taken along the line II-II in FIG. 1. In FIG. 8, a part of light beams emitted from the second light-emitting unit 20 of the light-emitting device 2 is represented by arrows. The light beam L21 is a light beam emitted from the central light-emitting unit 20-1. The light beam L22 is a light beam emitted from the outer light-emitting unit 20-2. The irradiation plane S is a plane perpendicular to the center line 1C of the lens 1 and is a plane irradiated with the light emitted from the light-emitting module 100.

As illustrated in FIG. 8, the light-emitting module 100 can emit the light beam L21 having a first light distribution half angle θ21, which has passed through the lens 1 when only the central light-emitting unit 20-1 is allowed to emit light, and the light beam L22 having a second light distribution half angle θ22, which has passed through the lens 1 when only the plurality of outer light-emitting units 20-2 are allowed to emit light. The first light distribution half angle θ21 is wider than the second light distribution half angle θ22. Note that in FIG. 8, for ease of explanation, light beams emitted from the centers of the respective light-emitting units are illustrated to explain that the light distribution angle of the irradiation light from the central light-emitting unit is wider than the light distribution angle of the irradiation light from the outer light-emitting unit.

The light beam L21 emitted from the central light-emitting unit 20-1 enters the lens portion 13 through the first light incident surface 11-1 and, after passing through the lens portion 13, exits from the light exit surface 12. The light beam L21 is refracted in a diverging direction by the negative refractive power obtained by the first light incident surface 11-1 of the light incident surface 11 and the flat surface 12-1 of the light exit surface 12. The light beam L21 is light having the wide-angle light distribution that travels in a direction opposite to a direction in which the center line 11C of the light incident surface 11 is positioned.

In the narrow-angle mode, the light beam L22 emitted from the outer light-emitting unit 20-2 enters the lens portion 13 through the second light incident surface 11-2 and, after passing through the lens portion 13, exits from the lens portion 13 through the convex exit surface 12-2. The light beam L22 is refracted in a converging direction by the positive refractive power obtained by the second light incident surface 11-2 of the light incident surface 11 and the convex exit surface 12-2 of the light exit surface 12. The light beam L22 is light having the narrow-angle light distribution that travels toward a side where the center line 11C of the light incident surface 11 is positioned, as compared with the light beam L21.

In FIG. 9, an upper end Q1 indicates an upper end of a convex exit surface 12-2. A lower end Q2 indicates a lower end of the convex exit surface 12-2. A tangent point J indicates a tangent point at an arbitrary position between the upper end Q1 and the lower end Q2 of the convex exit surface 12-2. An inclination angle φ of a curved surface indicates the inclination of the minute line segment of the convex exit surface 12-2 at the tangent point J.

An inclination angle φ preferably increases, in a cross section passing through the center line 1C of the lens 1, as the position approaches the lower end Q2 from the upper end Q1 of the convex exit surface 12-2 in the light-emitting module 100. Accordingly, of the light beams L22 emitted from one light-emitting point of the outer light-emitting unit 20-2, the light beam directed toward a side of the lower end Q2 of the convex exit surface 12-2 (the light beam having a large light distribution angle) is strongly converged by the convex exit surface 12-2, and the light beam directed toward a side of the upper end Q1 of the convex exit surface 12-2 (the light beam having a small light distribution angle) is weakly converged by the convex exit surface 12-2. As a result, both the light beam having a large light distribution angle and the light beam having a small light distribution angle among the light beams L22 are easily converged in the same direction, and narrow directivity can be easily obtained.

### First Modified Example of First Embodiment

Subsequently, a light-emitting module according to a first modified example of the first embodiment of the present disclosure will be described. The same names and reference characters as those in the previously described embodiment indicate the same members or configurations, or indicate members or configurations of the same quality, and a detailed description thereof is omitted as appropriate. This applies to the modified example and the embodiments which will be described hereinafter.

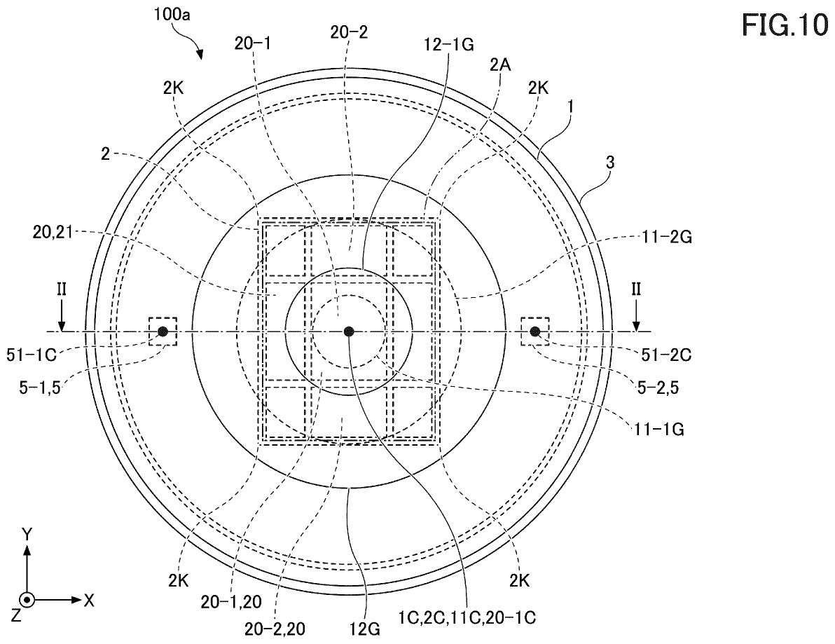

FIG. 10 is a schematic top view illustrating an overall configuration of a light-emitting module 100a according to the first modified example. As illustrated in FIG. 10, the light-emitting module 100a according to the first modified example differs from the light-emitting module 100 according to the first embodiment in that the light-emitting module 100a includes only the first light-emitting unit 5-1 and the first light-emitting unit 5-2 without including the first light-emitting unit 5-3. That is, the light-emitting module 100a includes two first light-emitting units 5.

Also in the light-emitting module 100a, the same effect as that of the light-emitting module 100 according to the first embodiment can be obtained.

### Second Modified Example of First Embodiment

Subsequently, a light-emitting module according to a second modified example of the first embodiment of the present disclosure will be described.

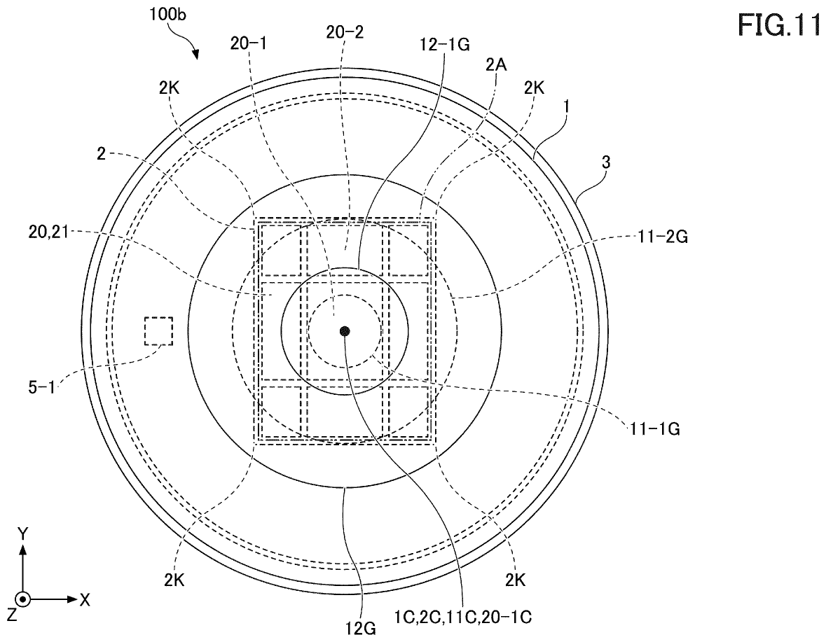

FIG. 11 is a schematic top view illustrating an overall configuration of a light-emitting module 100b according to the second modified example. As illustrated in FIG. 11, the light-emitting module 100b according to the second modified example differs from the light-emitting module 100 according to the first embodiment in that the light-emitting module 100b includes only the first light-emitting unit 5-1 without including the first light-emitting unit 5-2 and the first light-emitting unit 5-3. That is, the light-emitting module 100b includes one first light-emitting unit 5.

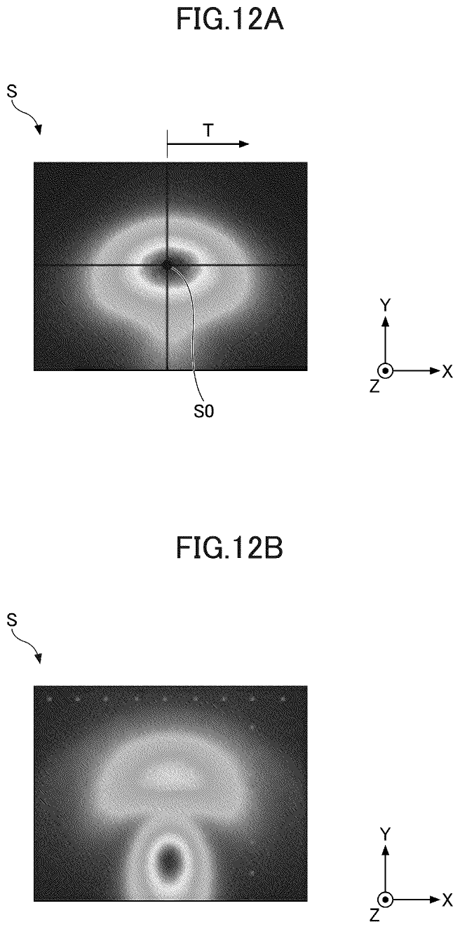

FIG. 12A is an image showing a simulation result of the illuminance distribution on the irradiation plane S when only the first light-emitting unit 5-1 is allowed to emit light in the light-emitting module 100b. Since the manner of viewing the illuminance distribution in FIG. 12A is the same as the manner of viewing the illuminance distribution in FIG. 5A, redundant description will be omitted.

FIG. 12B is an image showing a simulation result of an illuminance distribution of irradiation light emitted from a light-emitting module 100Y according to a second comparative example. The light-emitting module 100Y is a light-emitting module obtained by removing the first light-emitting unit 5-2 from the light-emitting module 100X illustrated in FIG. 5B and including only the first light-emitting unit 5-1.

As illustrated in FIG. 12B, in the light-emitting module 100Y according to the second comparative example, a finding has been obtained that the non-uniformity occurs in the illuminance distribution in the irradiation light on the irradiation plane S.

On the other hand, in the simulation result illustrated in FIG. 12A, a substantially elliptical illuminance distribution centered on the irradiation center S0 has been obtained. From this result, a finding has been obtained that, in the light-emitting module 100b, the unevenness in the illuminance distribution in the irradiation light can be reduced as compared with the light-emitting module 100Y according to the second comparative example in which the shape of the illuminance distribution is the distorted shape. As a result, a finding has been obtained that, in the light-emitting module 100b, the unevenness in the illuminance distribution in the irradiation light can be reduced.

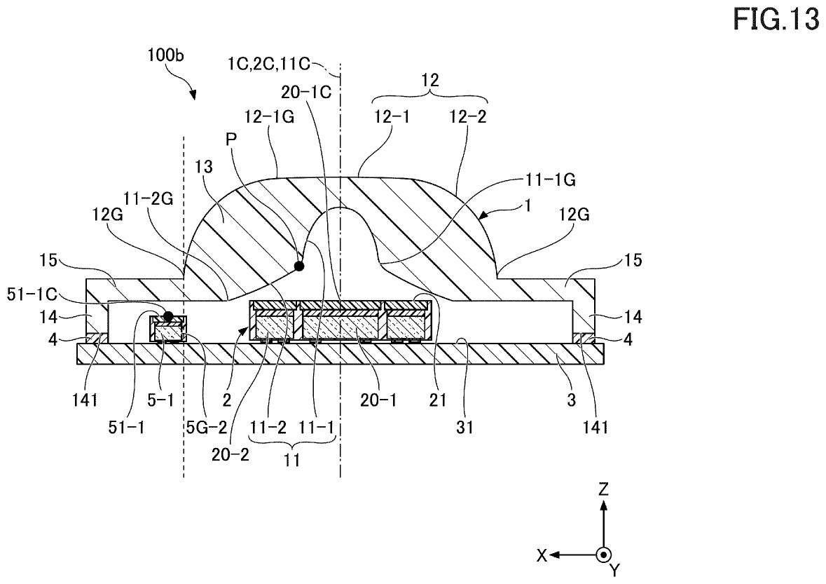

FIG. 13 is a schematic view illustrating a preferable positional relationship between the lens 1 and the first light-emitting unit 5-1 included in the light-emitting module 100b. As a result of study, a finding has been obtained that, in the light-emitting module 100b, in a top view, in a case in which the center of the light-emitting surface of the first light-emitting unit 5 overlaps the intersection point 12G between the convex exit surface 12-2 and the lens outer peripheral portion 15, or is positioned outside the intersection point 12G, a preferable illuminance distribution can be obtained. In particular, a finding has been obtained that, in a top view, in a case in which an outer edge 5G-2 of the first light-emitting unit 5 on a side where the center line 1C of the lens 1 is positioned overlaps the intersection point 12G between the convex exit surface 12-2 and the lens outer peripheral portion 15, an optimal illuminance distribution can be obtained. In other words, the at least one first light-emitting unit 5 is the single first light-emitting unit 5, and, in a top view, when the outer edge 5G-2 of the first light-emitting unit 5 on the side where the center line 1C of the lens 1 is positioned overlaps the intersection point 12G between the convex exit surface 12-2 and the lens outer peripheral portion 15, an optimal illuminance distribution can be obtained. As illustrated in FIGS. 6 and 13, an optimal positional relationship of the first light-emitting unit 5 differs between a case in which one first light-emitting unit 5 is provided and a case in which two first light-emitting units 5 are provided.

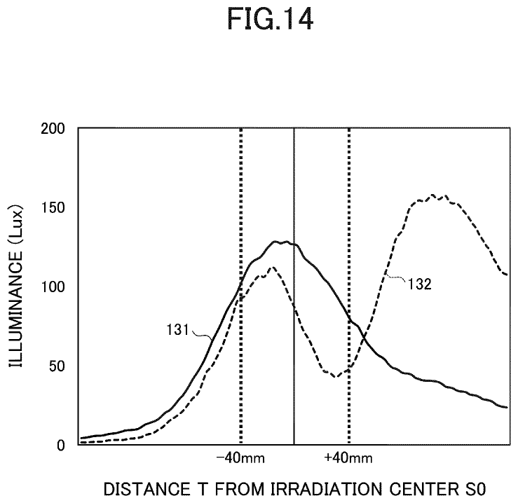

FIG. 14 is a graph showing a simulation result of an illuminance distribution in a cross section including the irradiation center S0 of the irradiation plane S of the irradiation light from the light-emitting module 100b. FIG. 14 illustrates the illuminance distribution on the irradiation plane S being positioned 150 mm away from the first light-emitting surface 51-1 in a direction orthogonal to the first light-emitting surface 51-1, for example, in the Z direction, and in a cross section including the irradiation center S0 of the irradiation plane S. The horizontal axis corresponds to the distance T illustrated in FIG. 12A.

In FIG. 14, a graph 131 shown by a solid line represents a simulation result regarding the light-emitting module 100b according to the second modified example of the first embodiment of the present disclosure. A graph 132 illustrated by a broken line represents a simulation result regarding the light-emitting module 100Y according to the second comparative example.

As illustrated in FIG. 14, the ratio of the minimum illuminance to the maximum illuminance at a distance T within the range from −40 mm to 40 mm on the irradiation plane is 38.5% in the light-emitting module 100Y according to the second comparative example, while the ratio is 63.5% in the light-emitting module 100b. Accordingly, it has been found that, in the light-emitting module 100b, the unevenness in the illuminance distribution in the irradiation light can be reduced. In the light-emitting module 100b according to the present embodiment, the ratio of the minimum illuminance to the maximum illuminance at a distance T within the range from −40 mm to 40 mm on the irradiation plane is, for example, greater than 40% and preferably 60% or more, more preferably 70% or more, and further preferably 80% or more.

By combining the simulation result regarding the light-emitting module 100 illustrated in FIG. 7 and the simulation result regarding the light-emitting module 100b illustrated in FIG. 14, the following can be said. That is, in the first embodiment of the present disclosure, on the irradiation plane S being positioned 150 mm away from the first light-emitting surface 51-1 in a direction orthogonal to the first light-emitting surface 51-1, and in a cross section including the irradiation center S0 of the irradiation plane S, the ratio of the minimum illuminance to the maximum illuminance at a distance T within the range from −40 mm to 40 mm on the irradiation plane is preferably greater than 60%. Accordingly, in the first embodiment of the present disclosure, the unevenness in the illuminance distribution in the irradiation light can be reduced.

### Third Modified Example of First Embodiment

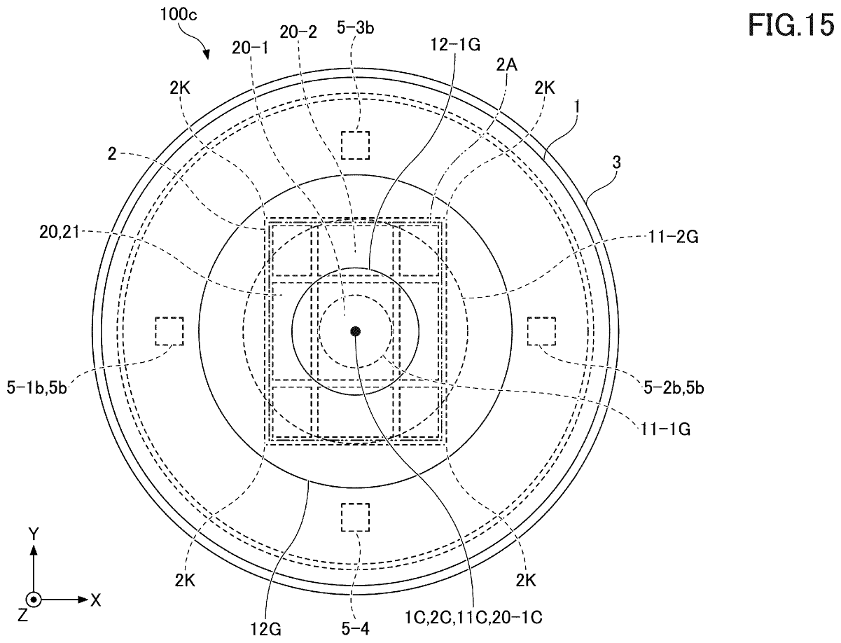

Subsequently, a light-emitting module according to a third modified example of the first embodiment of the present disclosure will be described. FIG. 15 is a schematic top view illustrating an overall configuration of a light-emitting module 100c according to the third modified example of the first embodiment of the present disclosure.

The light-emitting module 100c according to the third modified example of the first embodiment differs from the light-emitting module 100 according to the first embodiment in that the at least one first light-emitting unit 5 includes one or more blue light-emitting units 5-3b, one or more green light-emitting units 5b, and one or more red light-emitting units 5-4.

The blue light-emitting units 5-3b emit light having a light emission peak wavelength within a range from 400 nm to less than 490 nm. The green light-emitting units 5b emit light having a light emission peak wavelength within a range from 490 nm to less than 560 nm. The red light-emitting units 5-4 emit light having a light emission peak wavelength within a range from 560 nm to 680 nm. One or more of the blue light-emitting units 5-3b, one or more of the green light-emitting units 5b, and one or more of the red light-emitting units 5-4 are individually subjected to light emission control. On the irradiation plane S, the light emitted from each of the blue light-emitting units 5-3b, the green light-emitting units 5b, and the red light-emitting units 5-4 overlaps.

In an example illustrated in FIG. 15, one or more of the green light-emitting units 5b include a first green light-emitting unit 5-1b and a second green light-emitting unit 5-2b. In a top view, the first green light-emitting unit 5-1b and the second green light-emitting unit 5-2b are disposed at positions symmetrical with respect to the center line 1C of the lens 1. The first green light-emitting unit 5-1b can emit light having a light emission peak wavelength within a range from 490 nm to less than 530 nm. The second green light-emitting unit 5-2b can emit light having a light emission peak wavelength within a range from 530 nm to less than 560 nm.

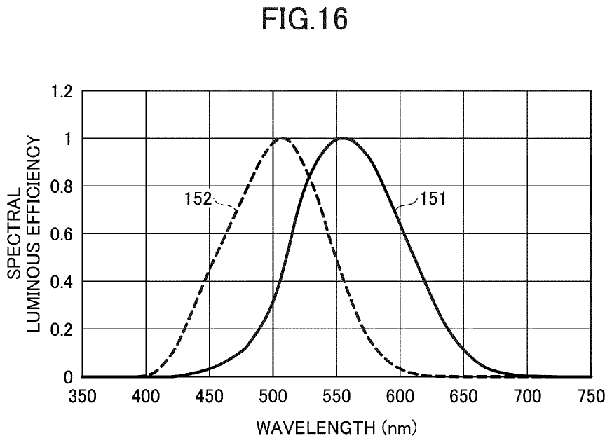

FIG. 16 is a graph showing a relative luminous efficiency curve in photopic vision and a relative luminous efficiency curve in scotopic vision. In FIG. 16, the graph 151 shows the relative luminous efficiency curve in photopic vision, and a graph 152 illustrates the relative luminous efficiency curve in scotopic vision. The light emitted from the first green light-emitting unit 5-1b is suitable light for photopic vision. The light emitted from the second green light-emitting unit 5-2b is suitable light for scotopic vision.

In the third modified example of the first embodiment of the present disclosure, the light emitted from each of the blue light-emitting units 5-3b, the green light-emitting units 5b, and the red light-emitting units 5-4, which are individually subjected to light emission control, overlaps on the irradiation plane S. By overlapping the light of respective colors on the irradiation plane S, the respective colors are mixed. Accordingly, in the third modified example of the first embodiment of the present disclosure, the light-emitting module 100c that allows color adjustment of irradiation light can be provided.

In the third modified example of the first embodiment of the present disclosure, the first green light-emitting unit 5-1b can emit light suitable for photopic vision, and the second green light-emitting unit 5-2b can emit light suitable for scotopic vision. Accordingly, the light-emitting module 100c can irradiate light suitable for photopic vision or scotopic vision by selectively using, for example, the first green light-emitting unit 5-1b and the second green light-emitting unit 5-2b, in accordance with brightness environments in which the light-emitting module 100c is used.

### Fourth Modified Example of First Embodiment

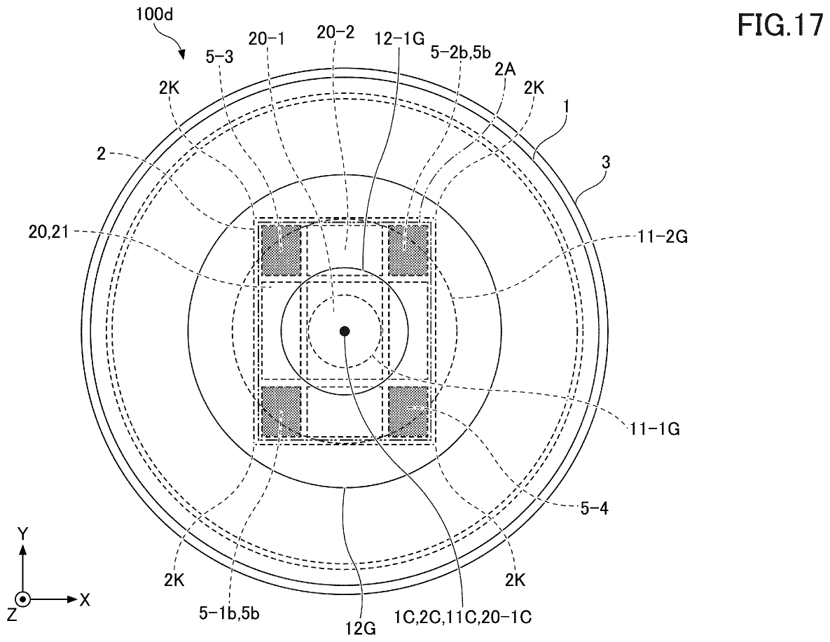

Subsequently, a light-emitting module according to a fourth modified example of the first embodiment of the present disclosure will be described. FIG. 17 is a schematic top view illustrating an overall configuration of a light-emitting module 100d according to the fourth modified example of the first embodiment of the present disclosure.

The light-emitting module 100d according to the fourth modified example of the first embodiment of the present disclosure differs from the light-emitting module 100 according to the first embodiment in that the covering member 25 integrally holds the at least one first light-emitting unit 5 and the plurality of second light-emitting units 20.

In an example illustrated in FIG. 17, the at least one first light-emitting unit 5 includes the blue light-emitting unit 5-3b, two of the green light-emitting units 5b, and the red light-emitting unit 5-4. The two green light-emitting units 5b include the first green light-emitting unit 5-1b and the second green light-emitting unit 5-2b. The blue light-emitting unit 5-3b, the first green light-emitting unit 5-1b, the second green light-emitting unit 5-2b, and the red light-emitting unit 5-4 are disposed at four corners of the light-emitting region 2A of the light-emitting device 2 in a top view. The covering member 25 included in the light-emitting device 2 integrally holds the blue light-emitting unit 5-3b, the first green light-emitting unit 5-1b, the second green light-emitting unit 5-2b, the red light-emitting unit 5-4, and five second light-emitting units 20. Accordingly, in the light-emitting device 2 included in the light-emitting module 100d, an occupied area of the light-emitting device 2 with respect to the substrate 3 can be reduced as compared with a case in which the first light-emitting unit 5 and the light-emitting device 2 are disposed apart from each other. This makes it easier to ensure a space for disposing other electronic components on the substrate 3. In addition, the area of the light-emitting region of the light-emitting device 2 including the first light-emitting unit 5 can be made smaller with respect to the planar size of the lens 1. As a result, the light emitted from the light-emitting device 2 can be easily controlled with high accuracy by the lens 1.

While preferred embodiments have been described in detail above, the present disclosure is not limited to the above-described embodiments.

Various modifications and substitutions can be made to the above-described embodiments without departing from the scope described in the claims.

The ordinal numbers, quantity, and other numbers used in the description of the embodiments are all exemplified to specifically describe the technique of the present disclosure, and the present disclosure is not limited to the numbers exemplified. In addition, the connection relationship between the constituent components is exemplified to specifically describe the technique of the present disclosure, and the connection relationship for implementing the function of the present disclosure is not limited thereto.

The lens and the light-emitting module of the present disclosure can control light distribution, and thus are suitable for use in applications such as lighting, camera flashes, and in-vehicle headlights. However, the lens and the light-emitting module of the present disclosure are not limited to these applications.

What is claimed is:

1. A light-emitting module comprising:
a lens comprising:
a light incident surface that is recessed upward, and
a light exit surface positioned on a side opposite to the light incident surface, the light exit surface comprising:
a flat surface orthogonal to a center line of the lens, and
a convex exit surface positioned outside the flat surface in a top view; and
at least one first light-emitting unit disposed below the lens and having a predetermined light distribution angle, each of the at least one first light-emitting unit comprising a first light-emitting surface, a center of the first light-emitting surface being positioned outside the flat surface in the top view, wherein
the light-emitting module is configured such that light beams emitted from a light-emitting point on the first light-emitting surface include:
a first light beam that exits upward through the lens above the first light-emitting surface, and
a second light beam totally reflected by the flat surface.

2. The light-emitting module according to claim 1, wherein:
the at least one first light-emitting unit comprises two first light-emitting units, the two first light-emitting units being disposed at symmetrical positions with respect to the center line of the lens in the top view.

3. The light-emitting module according to claim 1, wherein:
in a cross section comprising the center line of the lens and the first light-emitting unit, the lens comprises a lens outer peripheral portion positioned outside the convex exit surface, the lens outer peripheral portion having an incident surface and an exit surface, the incident surface and the exit surface being parallel to the first light-emitting surface, and
the center of the first light-emitting surface is positioned below the lens outer peripheral portion.

4. The light-emitting module according to claim 1, wherein:
the first light-emitting unit is configured to emit white light, blue light, green light, or red light.

5. The light-emitting module according to claim 1, wherein:
the at least one first light-emitting unit comprises:
one or more blue light-emitting units configured to emit light having a light emission peak wavelength within a range from 400 nm to less than 490 nm,
one or more green light-emitting units configured to emit light having a light emission peak wavelength within a range from 490 nm to less than 560 nm, and
one or more red light-emitting units configured to emit light having a light emission peak wavelength within a range from 560 nm to 680 nm, and light emitted from each of the blue light-emitting unit,
light emission of the one or more blue light-emitting units is separately controllable from light emission of the one or more green light-emitting units, light emission of the one or more blue light-emitting units is separately controllable from light emission of the one or more red light-emitting units, and light emission of the one or more green light-emitting units is separately controllable from light emission of the one or more red light-emitting units,
light emitted from the green light-emitting unit and light emitted from the red light-emitting unit overlap on an irradiation plane.

6. The light-emitting module according to claim 5, wherein:
the one or more green light-emitting units comprise
a first green light-emitting unit configured to emit light having a light emission peak wavelength within a range from 490 nm to less than 530 nm, and
a second green light-emitting unit configured to emit light having a light emission peak wavelength within a range from 530 nm to less than 560 nm.

7. The light-emitting module according to claim 1, wherein:
on an irradiation plane positioned 150 mm away from the first light-emitting surface in a direction orthogonal to the first light-emitting surface, in a cross section comprising an irradiation center of the irradiation plane, a ratio of a minimum illuminance to a maximum illuminance at a distance within a range from −40 mm to 40 mm from the irradiation center is greater than 60%.

8. The light-emitting module according to claim 1, wherein:
the at least one first light-emitting unit is one first light-emitting unit, and
in a cross section comprising the center line of the lens and the one first light-emitting unit:
the lens comprises a lens outer peripheral portion positioned outside the convex exit surface, and
in the top view, an outer edge of the first light-emitting surface on a side of the center line of the lens coincides with an intersection point between the convex exit surface and the lens outer peripheral portion.

9. The light-emitting module according to claim 1, wherein:
the at least one first light-emitting unit comprises two of the first light-emitting units,
in a cross section comprising the center line of the lens and the two first light-emitting units,
the lens comprises a lens outer peripheral portion positioned outside the convex exit surface, and
in the top view, an outer edge of the first light-emitting surface on a side opposite to a side of the center line of the lens coincides with an intersection point between the convex exit surface and the lens outer peripheral portion.

10. The light-emitting module according to claim 1, further comprising:
a light-emitting device comprising:
a plurality of second light-emitting units including:
a central light-emitting unit comprising a second light-emitting surface, and
one or more outer light-emitting units disposed outside the central light-emitting unit in the top view, wherein:
a center of the second light-emitting surface is positioned below the flat surface, and
a light distribution angle of irradiation light by the central light-emitting unit through the lens is wider than a light distribution angle of irradiation light by the outer light-emitting unit through the lens.

11. The light-emitting module according to claim 10, wherein:
in a cross section comprising the center line of the lens, the light incident surface comprises:
an inflection point at which a concave surface changes to a convex surface,
a first light incident surface positioned above the inflection point, the first light incident surface comprising the concave surface continuous with the inflection point, the first light incident surface positioned at a central portion of the light incident surface in the top view, and
a second light incident surface positioned below the inflection point, the second light incident surface comprising the convex surface continuous with the inflection point, the second light incident surface positioned outside the first light incident surface in the top view.

12. The light-emitting module according to claim 11, wherein:
in the top view, at least one of the outer light-emitting units is disposed overlapping the second light incident surface.

13. The light-emitting module according to claim 10, further comprising:
a covering member integrally holding the plurality of second light-emitting units.

14. The light-emitting module according to claim 13, wherein:
the covering member integrally holds the at least one first light-emitting unit and the plurality of second light-emitting units.

15. The light-emitting module according to claim 10, wherein:
the at least one first light-emitting unit is disposed apart from the light-emitting device with a space present between the at least one first light-emitting unit and the light-emitting device.
